(19) United States
(12) Patent Application Publication
(10) Pub. No.: US 2026/0362609 A1
(43) Pub. Date: Nov. 12, 2026

(54) FLEXIBLE DISPLAY AND ELECTRONIC DEVICE COMPRISING SAME

(71) Applicant: Samsung Electronics Co., Ltd., Suwon-si (KR)

(72) Inventors: Yongho KIM, Suwon-si (KR); Junghyung PARK, Suwon-si (KR); Hyeryun YOO, Suwon-si (KR); Kwonho SONG, Suwon-si (KR); Hyunsuk JUNG, Suwon-si (KR)

(21) Appl. No.: 19/725,876

(22) Filed: Jun. 30, 2026

Related U.S. Application Data
(63) Continuation of application No. PCT/KR2024/021414, filed on Dec. 30, 2024.

(30) Foreign Application Priority Data
Jan. 5, 2024 (KR) 10-2024-0002108
Mar. 13, 2024 (KR) 10-2024-0035193

(51) Int. Cl. H05K 5/00; H05K 9/00

(52) U.S. Cl. CPC H05K 5/0018; H05K 9/0083

(57) ABSTRACT

An electronic device according to one embodiment of the present invention may include a first housing, a second housing, and a display device disposed on the first housing and the second housing. The display device may comprise: a flexible display panel, a digitizer disposed below the flexible display panel, a support plate disposed below the digitizer and including a polymer material, and a conductive layer disposed between the digitizer and the support plate and plated on the surface of the support plate.

### CROSS-REFERENCE TO RELATED APPLICATION(S)

This application is a continuation application, claiming priority under 35 U.S.C. § 365 (c), of an International application No. PCT/KR2024/021414, filed on Dec. 30, 2024, which is based on and claims the benefit of a Korean patent application number 10-2024-0002108, filed on Jan. 5, 2024, in the Ministry of Intellectual Property Office (MOIP), and of a Korean patent application number 10-2024-0035193, filed on Mar. 13, 2024, in the Ministry of Intellectual Property Office (MOIP), the disclosure of each of which is incorporated by reference herein in its entirety.

### BACKGROUND

### 1. Field

An embodiment disclosed in this document relates to a flexible display and an electronic device including the same.

### 2. Description of Related Art

Owing to the remarkable development of information and communication technology and semiconductor technology, the supply and use of various electronic devices is rapidly increasing. In particular, recent electronic devices are being developed to be portable and capable of communication.

An electronic device may refer to a device that performs a specific function according to a mounted program, ranging from home appliances to electronic organizers, portable multimedia players, mobile communication terminals, tablet personal computers (PCs), video/audio devices, desktop/laptop computers, and vehicle navigation systems. For example, such electronic devices may output stored information as sound or video. As the degree of integration of electronic devices increases and ultra-high-speed, high-capacity wireless communication becomes common, recently, various functions may be mounted in one electronic device, such as a mobile communication terminal. For example, not only a communication function but also entertainment functions, such as games, multimedia functions, such as music/video playback, communication and security functions for mobile banking and the like, and functions, such as schedule management and an electronic wallet are being integrated into one electronic device. Such electronic devices are being miniaturized so that a user may conveniently carry them.

As the use of personal or portable communication devices, such as smartphones becomes common, user demands for portability and convenience of use are increasing. For example, a touchscreen display is an output device that outputs a screen, for example, visual information, and may provide a virtual keypad that replaces a mechanical input device (e.g., a button-type input device). As a result, a portable communication device or an electronic device has been able to provide the same or further enhanced usability (e.g., a larger screen) while being miniaturized. Meanwhile, as displays that are flexible, for example, foldable or rollable, are commercialized, the portability and convenience of use of electronic devices are expected to be further enhanced.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a flexible display and an electronic device including the same.

Additional aspects will be set forth in part in the description which follows and, in part, will be apparent from the description, or may be learned by practice of the presented embodiments.

An electronic device according to an embodiment of the disclosure may comprise a first housing, a second housing, and a display device disposed on the first housing and the second housing. The display device may comprise a flexible display panel, a digitizer disposed below the flexible display panel, a support plate disposed below the digitizer and including a polymer material, and a conductive layer disposed between the digitizer and the support plate and plated on a surface of the support plate.

A display device according to an embodiment of the disclosure may comprise a flexible display panel, a digitizer disposed below the flexible display panel, a shielding layer disposed below the digitizer and including a magnetic metal powder (MMP), a support plate disposed under the shielding layer and including a polymer material, and a conductive layer disposed between the shielding layer and the support plate and plated on a surface of the support plate.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIG. 2 is a view illustrating an unfolded state of an electronic device according to an embodiment of the disclosure;

FIG. 3 is a view illustrating a folded state of an electronic device according to an embodiment of the disclosure;

FIG. 4 is an exploded perspective view of an electronic device according to an embodiment of the disclosure;

FIG. 5 is a cross-sectional view of a flexible display device of an electronic device according to an embodiment of the disclosure;

FIG. 6A is an enlarged view illustrating an enlargement of a portion P of a structure of a display device according to an embodiment of the disclosure;

FIG. 6B is an enlarged view illustrating an enlargement of a portion P of a structure of a display device according to an embodiment of the disclosure;

FIG. 7A is an enlarged view illustrating an enlargement of a portion P of a structure of a display device according to an embodiment of the disclosure;

FIG. 7B is an enlarged view illustrating an enlargement of a portion P of a structure of a display device according to an embodiment of the disclosure;

FIG. 8 is a view illustrating a result of two-dimensional (2D) scanning of a support layer structure disposed under a digitizer among a general display device and a display device according to an embodiment of the disclosure;

FIG. 9 is a flowchart illustrating a surface plating process on a support plate of a support layer according to an embodiment of the disclosure;

FIG. 10 is a view illustrating a cross-section of a support layer after a surface plating process of the flowchart of FIG. 9 according to an embodiment of the disclosure;

FIG. 11A is a view illustrating a result of a peel test at room temperature considering rework of a display device according to an embodiment of the disclosure; and

FIG. 11B is a view illustrating a result of a peel test at high temperature (e.g., approximately 75 °C) considering rework of a display device according to an embodiment of the disclosure.

The same reference numerals are used to represent the same elements throughout the drawings.

### DETAILED DESCRIPTION

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

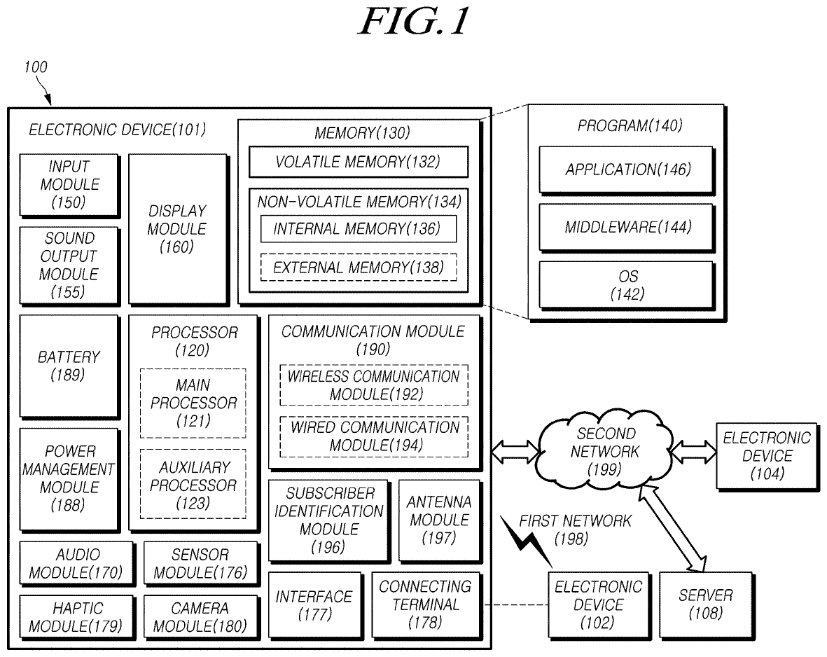

FIG. 1 is a block diagram illustrating an electronic device in a network environment according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thererto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mm Wave antenna module. According to an embodiment, the mm Wave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

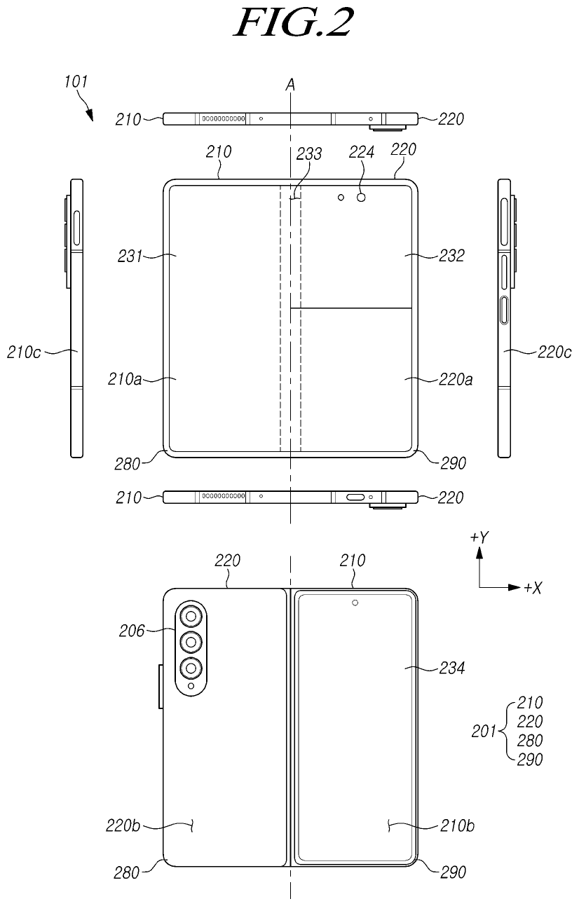

FIG. 2 is a view illustrating an unfolded state of an electronic device according to an embodiment of the disclosure.

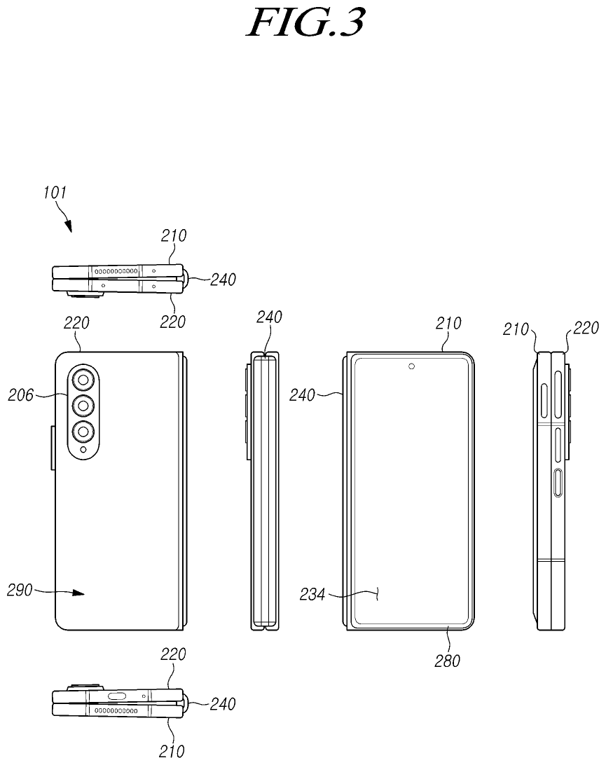

FIG. 3 is a view illustrating a folded state of an electronic device according to an embodiment of the disclosure.

Referring to FIGS. 2 and 3, the electronic device 101 may comprise a housing 201, a hinge cover 240 covering a foldable portion of the housing 201, and a display device 230 disposed within a space formed by the housing 201. According to an embodiment of the disclosure, a surface on which a screen output from the display device 230 is exposed is defined as a front surface (e.g., a first front surface 210a and a second front surface 220a) of the electronic device 101. A surface opposite to the front surface is defined as a rear surface (e.g., a first rear surface 210b and a second rear surface 220b) of the electronic device 101. A surface surrounding the space between the front surface and the rear surface is defined as a side surface (e.g., a first side surface 210c and a second side surface 220c) of the electronic device 101. The side surface of the electronic device 101 may be a side surface of at least one of the first housing 210 or the second housing 220.

The electronic device 101 of FIGS. 2 and 3 may be referred to as a foldable electronic device, a portable electronic device, or a portable foldable electronic device. According to an embodiment of the disclosure, the housing 201 may be referred to as a foldable housing. The display device 230 may be referred to as a “flexible display.”

According to an embodiment of the disclosure, the housing 201 may comprise a first housing 210, a second housing 220 rotatable with respect to the first housing 210, a first rear cover 280, and a second rear cover 290. The housing 201 of the electronic device 101 is not limited to the shape and combination illustrated in FIGS. 2 and 3, and may be implemented by other shapes or a combination and/or coupling of components. For example, the first housing 210 and the first rear cover 280 may be integrally formed, and the second housing 220 and the second rear cover 290 may be integrally formed.

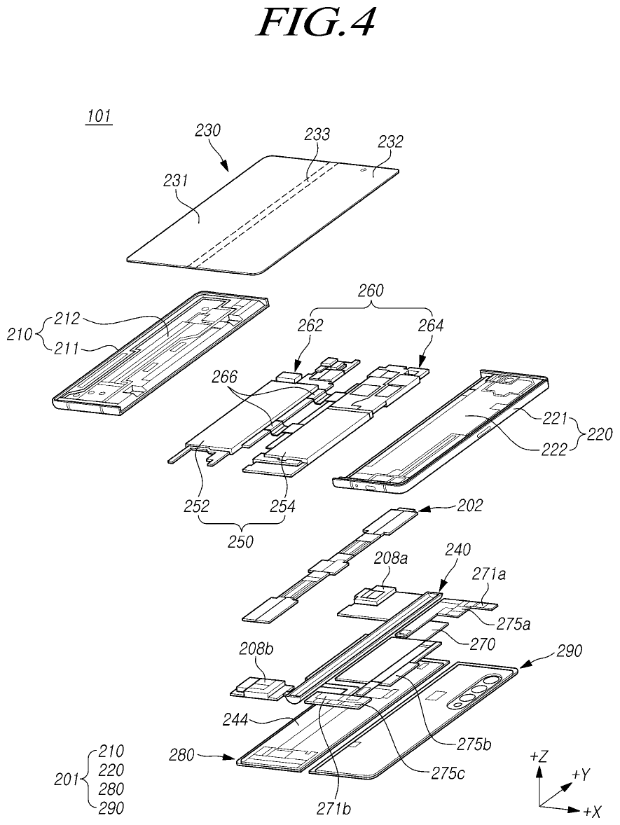

According to an embodiment of the disclosure, the first housing 210 is connected to a hinge structure (e.g., the hinge assembly 202 of FIG. 4), and may comprise a first front surface 210a facing a first direction and a first rear surface 210b facing a second direction opposite to the first direction. The second housing 220 is connected to the hinge assembly 202, comprises a second front surface 220a facing a third direction and a second rear surface 220b facing a fourth direction opposite to the third direction, and may rotate with respect to the first housing 210 about the hinge assembly 202. Accordingly, the electronic device 101 may change into a folded state or an unfolded state. In the electronic device 101, in the folded state, the first front surface 210a may face the second front surface 220a, and in the unfolded state, the third direction may be identical to the first direction. Hereinafter, unless otherwise mentioned, directions are described with reference to the unfolded state of the electronic device 101.

According to an embodiment of the disclosure, the first housing 210 and the second housing 220 are disposed on both sides about a folding axis A, and may have an overall symmetrical shape with respect to the folding axis A. As described later, the angle or distance formed between the first housing 210 and the second housing 220 may vary depending on whether the state of the electronic device 101 is an unfolded state, a folded state, or an intermediate state. According to an embodiment of the disclosure, the second housing 220 further comprises a sensor region 224 in which sensors (e.g., a front camera) are disposed, but may have a mutually symmetrical shape in regions other than this.

According to an embodiment of the disclosure, the first housing 210 and the second housing 220 are disposed on both sides about the folding axis A, and the folding axis A may be a plurality of (e.g., two) parallel folding axes. In the disclosure, the folding axis A is provided along a length direction (Y-axis direction) of the electronic device 101, but the direction of the folding axis A is not limited thereto. For example (not illustrated), the electronic device 101 may comprise a folding axis extending along a width direction (e.g., an X-axis direction).

According to an embodiment of the disclosure, the electronic device 101 may comprise a structure to which a digital pen may be attached. For example, the electronic device 101 may comprise a magnetic body configured to attach the digital pen to a side surface of the first housing 210 or a side surface of the second housing 220. According to an embodiment of the disclosure, the electronic device 101 may comprise a structure into which a digital pen may be inserted. For example, a hole (not illustrated) into which the digital pen may be inserted may be formed in the side surface of the first housing 210 or the side surface of the second housing 220 of the electronic device 101.

According to an embodiment of the disclosure, at least a portion of the first housing 210 and the second housing 220 may be formed of a metal material or a non-metal material having a rigidity of a selected magnitude to support the display device 230. The at least a portion formed of the metal material may provide a ground plane of the electronic device 101, and may be electrically connected to a ground line formed on a printed circuit board (e.g., the substrate part 260 of FIG. 4).

According to an embodiment of the disclosure, the sensor region 224 may be formed to have a predetermined area adjacent to one edge or one corner of the second housing 220. However, the arrangement, shape, and size of the sensor region 224 are not limited to the illustrated example. For example, in an embodiment of the disclosure, the sensor region 224 may be provided at another corner of the second housing 220 or at an arbitrary region between an upper corner and a lower corner, or at the first housing 210. In an embodiment of the disclosure, components for performing various functions embedded in the electronic device 101 may be exposed on the front surface of the electronic device 101 through the sensor region 224, or through one or more openings provided in the sensor region 224. In an embodiment of the disclosure, the components may comprise various kinds of sensors. The sensor may comprise, for example, at least one of a front camera, a receiver, or a proximity sensor.

According to an embodiment of the disclosure, the first rear cover 280 may be disposed on one side of the folding axis A on the rear surface of the electronic device 101. The first rear cover 280 may have a substantially rectangular periphery, and the periphery may be surrounded by the first housing 210. According to an embodiment of the disclosure, the second rear cover 290 is disposed on the other side of the folding axis A on the rear surface of the electronic device 101, and its periphery may be surrounded by the second housing 220.

According to an embodiment of the disclosure, the first rear cover 280 and the second rear cover 290 may have a substantially symmetrical shape about the folding axis A. However, the first rear cover 280 and the second rear cover 290 do not necessarily have a mutually symmetrical shape, and in another embodiment of the disclosure, the electronic device 101 may comprise the first rear cover 280 and the second rear cover 290 of various shapes.

According to an embodiment of the disclosure, the first rear cover 280, the second rear cover 290, the first housing 210, and the second housing 220 may form a space in which various components (e.g., a printed circuit board or a battery) of the electronic device 101 may be disposed. According to an embodiment of the disclosure of the disclosure, one or more components may be disposed on or visually exposed at the rear surface of the electronic device 101. For example, at least a portion of a sub-display device (e.g., the sub-display device 244 of FIG. 4) may be visually exposed through at least a portion of the first rear cover 280. According to an embodiment of the disclosure, one or more components or sensors may be visually exposed through at least a portion of the second rear cover 290. According to an embodiment of the disclosure, the sensor may comprise a proximity sensor and/or a camera module 206 (e.g., a rear camera).

According to an embodiment of the disclosure, the front camera exposed on the front surface of the electronic device 101 through one or more openings provided in the sensor region 224, or the camera module 206 exposed through at least a portion of the second rear cover 290, may comprise one or a plurality of lenses, an image sensor, and/or an image signal processor. In an embodiment of the disclosure, two or more lenses (an infrared camera, wide-angle and telephoto lenses) and image sensors may be disposed on one surface of the electronic device 101.

According to an embodiment of the disclosure, the hinge cover 240 is disposed between the first housing 210 and the second housing 220, and may cover an internal component (e.g., the hinge assembly 202 of FIG. 4). According to an embodiment of the disclosure, the hinge cover 240 may be covered by a portion of the first housing 210 and the second housing 220, or exposed to the outside, depending on the state (a flat state or a folded state) of the electronic device 101.

According to an embodiment of the disclosure, as illustrated in FIG. 2, when the electronic device 101 is in an unfolded state, the hinge cover 240 may be covered by the first housing 210 and the second housing 220 and not exposed. As another example, as illustrated in FIG. 3, when the electronic device 101 is in a folded state (e.g., a fully folded state), the hinge cover 240 may be exposed to the outside between the first housing 210 and the second housing 220. As another example, when the first housing 210 and the second housing 220 are in an intermediate state in which they are folded with a certain angle, the hinge cover 240 may be partially exposed to the outside between the first housing 210 and the second housing 220. However, in this case, the exposed region may be smaller than in the fully folded state. According to an embodiment of the disclosure, the hinge cover 240 may comprise a curved surface.

According to an embodiment of the disclosure, the display device 230 may be disposed in a space formed by the housing 201. For example, the display device 230 is seated on a recess formed by the housing 201, and may constitute most of the front surface of the electronic device 101. Accordingly, the front surface of the electronic device 101 may comprise the display device 230 and a partial region of the first housing 210 adjacent to the display device 230 and a partial region of the second housing 220 adjacent to the display device 230. The rear surface of the electronic device 101 may comprise the first rear cover 280, a partial region of the first housing 210 adjacent to the first rear cover 280, the second rear cover 290, and a partial region of the second housing 220 adjacent to the second rear cover 290.

According to an embodiment of the disclosure, the display device 230 may comprise a plurality of displays spaced apart from each other. For example, the display device 230 may comprise a first display region 231 disposed on the first housing 210 and a second display region 232 disposed on the second housing 220. According to an embodiment of the disclosure, the first display region 231 and the second display region 232 may rotate with respect to the folding axis A.

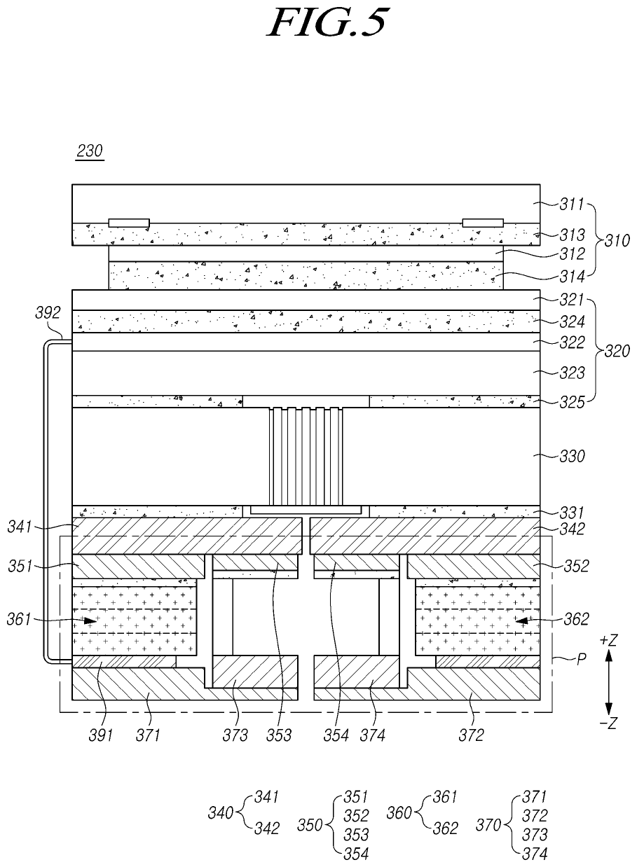

According to an embodiment of the disclosure, the display device 230 may refer to a display in which at least a partial region may be deformed into a flat surface or a curved surface. For example, the display device 230 may be a foldable or flexible display. According to an embodiment of the disclosure, the display device 230 may comprise a folding region 233, a first display region 231 disposed on one side (e.g., the left side of the folding region 233 illustrated in FIG. 2) with respect to the folding region 233, and a second display region 232 disposed on the other side (e.g., the right side of the folding region 233 illustrated in FIG. 2). However, the region division of the display device 230 is, and the display device 230 may be divided into a plurality of (e.g., four or more, or two) regions depending on a structure or function. For example, in the embodiment illustrated in FIG. 2, the regions of the display device 230 may be divided by the folding region 233 extending parallel to the Y-axis or by the folding axis A, but in another embodiment of the disclosure, the regions of the display device 230 may be divided with respect to another folding region (e.g., a folding region parallel to the X-axis) or another folding axis (e.g., a folding axis parallel to the X-axis). According to an embodiment of the disclosure, the display device 230 may be coupled to or disposed adjacent to a touch sensing circuit, a pressure sensor capable of measuring the intensity (pressure) of a touch, and/or a digitizer (e.g., the digitizer 340 of FIG. 5) configured to detect a magnetic-field-type stylus pen.

According to an embodiment of the disclosure, the first display region 231 and the second display region 232 may have an overall symmetrical shape about the folding region 233. According to an embodiment (not illustrated) of the disclosure, the second display region 232 may, unlike the first display region 231, comprise a notch cut according to the presence of the sensor region 224, but may have a shape symmetrical to the first display region 231 in regions other than this. In other words, the first display region 231 and the second display region 232 may comprise a portion having a shape symmetrical to each other and a portion having a shape asymmetrical to each other.

Hereinafter, the operation of the first housing 210 and the second housing 220 and each region of the display device 230 according to the state (e.g., a flat state, or an unfolded state, and a folded state) of the electronic device 101 will be described.

According to an embodiment of the disclosure, when the electronic device 101 is in a flat state (e.g., FIG. 2), the first housing 210 and the second housing 220 may be disposed to form an angle of substantially 180 degrees and face the same direction. The surface of the first display region 231 of the display device 230 and the surface of the second display region 232 form 180 degrees with each other, and may face the same direction (e.g., the front direction of the electronic device). The folding region 233 may form the same plane as the first display region 231 and the second display region 232.

According to an embodiment of the disclosure, when the electronic device 101 is in a folded state (e.g., FIG. 3), the first housing 210 and the second housing 220 may be disposed to face each other. The surface of the first display region 231 of the display device 230 and the surface of the second display region 232 form a narrow angle (e.g., between 0 degrees and 10 degrees) with each other, and may face each other. At least a portion of the folding region 233 may be formed of a curved surface having a predetermined curvature.

According to an embodiment of the disclosure, when the electronic device 101 is in an intermediate state (not illustrated), the first housing 210 and the second housing 220 may be disposed at a certain angle with each other. The surface of the first display region 231 of the display device 230 and the surface of the second display region 232 may form an angle larger than that in the folded state and smaller than that in the unfolded state. At least a portion of the folding region 233 may be formed of a curved surface having a predetermined curvature, and the curvature at this time may be smaller than that in the folded state.

FIG. 4 is an exploded perspective view illustrating an electronic device according to an embodiment of the disclosure.

Referring to FIG. 4, the electronic device 101 may comprise a housing 201, a display device 230, a hinge assembly 202, a battery 250, and a substrate part 260. The housing 201 may comprise a first housing 210, a second housing 220, a first rear cover 280, and a second rear cover 290. The configuration of the first housing 210, the second housing 220, the hinge cover 240, the first rear cover 280, and the second rear cover 290 of FIG. 4 may be identical in whole or part to the configuration of the first housing 210, the second housing 220, the hinge cover 240, the first rear cover 280, and the second rear cover 290 of FIGS. 2 and/or 3.

According to an embodiment of the disclosure, the first housing 210 and the second housing 220 may be assembled with each other so as to be coupled to both sides of the hinge assembly 202. According to an embodiment of the disclosure, the first housing 210 may comprise a first support region 212 capable of supporting a component (e.g., a first circuit board 262 and/or a first battery 252) of the electronic device 101 and a first side wall 211 surrounding at least a portion of the first support region 212. The first side wall 211 may comprise a first side surface (e.g., the first side surface 210c of FIG. 2) of the electronic device 101. According to an embodiment of the disclosure, the second housing 220 may comprise a second support region 222 capable of supporting a component (e.g., a second circuit board 264 and/or a second battery 254) of the electronic device 101 and a second side wall 221 surrounding at least a portion of the second support region 222. The second side wall 221 may comprise a second side surface (e.g., the second side surface 220c of FIG. 2) of the electronic device 101.

According to an embodiment of the disclosure, the display device 230 may comprise a first display region 231, a second display region 232, a folding region 233, and a sub-display device 244. The configuration of the first display region 231, the second display region 232, and the folding region 233 of FIG. 3 may be identical in whole or part to the configuration of the first display region 231, the second display region 232, and the folding region 233 of FIGS. 1 and/or 2.

According to an embodiment of the disclosure, the sub-display device 244 may display a screen in a direction different from that of the display regions 231 and 232. For example, the sub-display device 234 may output a screen in a direction opposite to the first display region 231. According to an embodiment of the disclosure, the sub-display device 234 may be disposed on the first rear cover 280.

According to an embodiment of the disclosure, the battery 250 may comprise a first battery 252 disposed within the first housing 210 and a second battery 254 disposed within the second housing 220. According to an embodiment of the disclosure, the first battery 252 is connected to the first circuit board 262, and the second battery 254 may be connected to the second circuit board 264. According to an embodiment of the disclosure, the battery 250 may supply power to at least one component of the electronic device 101. According to an embodiment of the disclosure, the battery 250 may comprise, for example, a non-rechargeable primary cell, a rechargeable secondary cell, or a fuel cell.

According to an embodiment of the disclosure, the substrate part 260 may comprise a first circuit board 262 disposed within the first housing 210 and a second circuit board 264 disposed within the second housing 220. According to an embodiment of the disclosure, the first circuit board 262 and the second circuit board 264 may be electrically connected by at least one flexible circuit board 266. According to an embodiment of the disclosure, at least a portion of the flexible circuit board 266 may be disposed across the hinge assembly 202. According to an embodiment of the disclosure, the first circuit board 262 and the second circuit board 264 may be disposed inside a space formed by the first housing 210, the second housing 220, the first rear cover 280, and the second rear cover 290. Components for implementing various functions of the electronic device 101 may be disposed on the first circuit board 262 and the second circuit board 264.

According to an embodiment of the disclosure, the electronic device 101 may comprise speakers 208a and 208b. According to an embodiment of the disclosure, the speakers 208a and 208b may convert an electrical signal into sound. According to an embodiment of the disclosure, the speakers 208a and 208b may be disposed inside a space formed by the first housing 210, the second housing 220, the first rear cover 280, and the second rear cover 290. According to an embodiment of the disclosure, the speakers 208a and 208b may comprise an upper speaker 208a located at an upper portion (+Y direction) of the electronic device 101 and a lower speaker 208b located at a lower portion (−Y direction) of the electronic device 101. In the disclosure, the speakers 208a and 208b are illustrated as being located within one housing (e.g., the first housing 210 of FIG. 4), but this is an optional structure. For example, the speakers 208a and 208b may be located within at least one of the first housing 210 or the second housing 220. The configuration of the speakers 208a and 208b of FIG. 4 may be identical in whole or part to the configuration of the sound output module 155 of FIG. 1.

According to an embodiment of the disclosure, the electronic device 101 may comprise a rear member 270 (or a rear case). According to an embodiment of the disclosure, the rear member 270 may be disposed within the housing 201 (e.g., the second housing 220). According to an embodiment of the disclosure, the rear member 270 may accommodate at least one antenna 275.

According to an embodiment of the disclosure, the electronic device 101 may comprise an antenna 275. The antennas 275a and 275b may comprise, for example, an ultra wide band (UWB) antenna 275a, a near field communication (NFC) antenna, a wireless charging antenna, and/or a magnetic secure transmission (MST) antenna 275b. The antenna 275 may, for example, perform near field communication with an external device or wirelessly transmit and receive power required for charging.

In an embodiment of the disclosure, an antenna structure may be formed by a portion of the housing 201 or a combination thereof. For example, the antenna 275 may comprise a communication antenna 275c that is at least partially exposed to the outside of the electronic device 101 and forms at least a portion of the outside of the electronic device 101. The communication antenna 275c may be used for communication (e.g., Wi-Fi) with an external electronic device. The communication antenna 275c may be connected to an upper portion 271a or a lower portion 271b of the rear member 270.

In the following detailed description, a configuration in which a pair of housings (or referred to as a ‘housing’) are rotatably coupled by a hinge structure (or referred to as a ‘hinge structure’) may be illustrated. However, it is noted that such an embodiment does not limit the electronic device according to the various embodiments disclosed in this document. For example, the electronic device according to the various embodiments disclosed in this document may comprise three or more housings, and the “pair of housings” in the embodiments disclosed below may mean “two housings that are rotatably coupled to each other among the three or more housings.”

Hereinafter, the structure of the display device 230 will be described below.

FIG. 5 is a cross-sectional view illustrating a flexible display device 230 of an electronic device according to an embodiment of the disclosure.

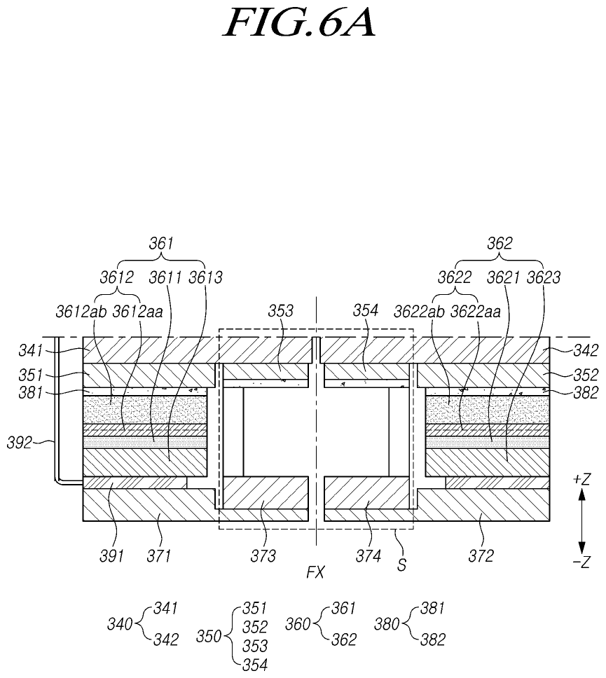

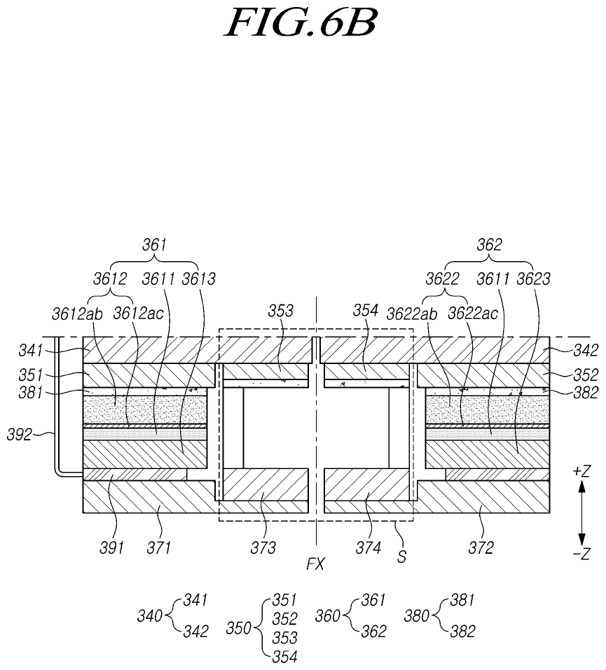

FIG. 6A is an enlarged view enlarging a portion P of the structure of a display device according to an embodiment of the disclosure.

FIG. 6B is an enlarged view enlarging a portion P of the structure of a display device according to an embodiment of the disclosure.

According to an embodiment of the disclosure, an electronic device (e.g., the electronic device 101 of FIGS. 1 to 4) may comprise a flexible display device 230.

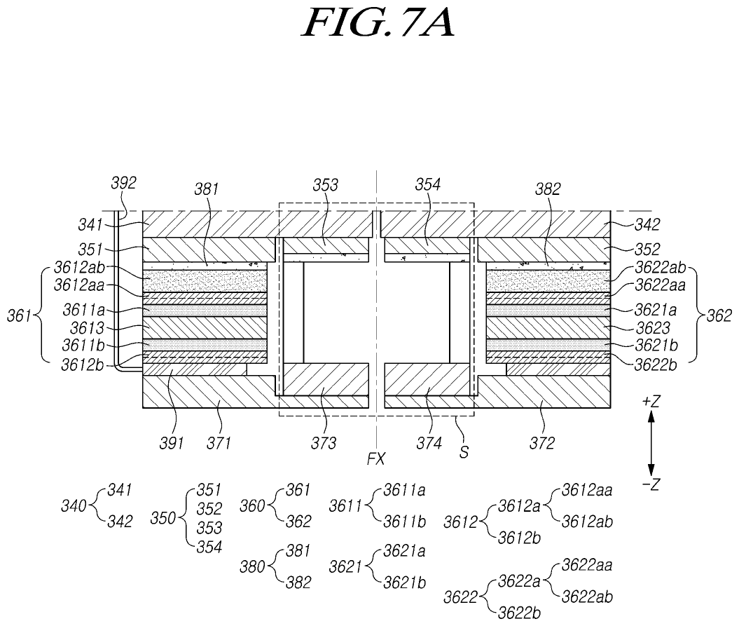

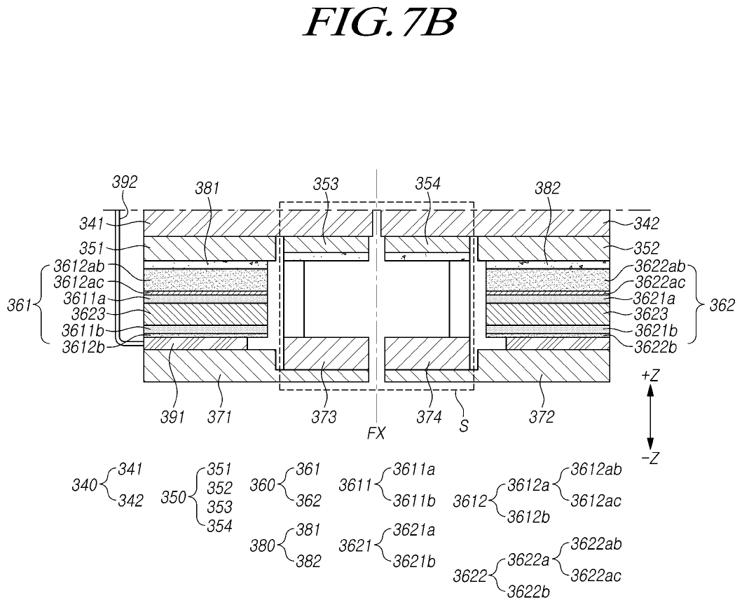

The configuration of the flexible display device 230 of FIGS. 5, 6A, and 6B may be partially or wholly identical to the configuration of the display module 160 of FIG. 1 and/or the display device 230 of FIGS. 2 to 4. The embodiment of FIGS. 5, 6A, and 6B may be selectively combined with the embodiment of FIGS. 7A, 7B, and 8 to 10.

According to an embodiment of the disclosure, the display device 230 may comprise a first layer 310, a second layer 320, a reinforcement layer 330, a digitizer 340, a shielding layer 350, and a support layer 360.

According to an embodiment of the disclosure, the display device 230 may comprise a first layer 310. The first layer 310 may be a portion exposed to the outside of the electronic device 101.

According to an embodiment of the disclosure, the first layer 310 may comprise a protective film 311. The protective film 311 may be a portion exposed to the outside of the electronic device 101. According to an embodiment of the disclosure, the first layer 310 may comprise a window 312. The window 312 may be coupled to the protective film 311. The window 312 may be thin glass or ultra thin glass. The first layer 310 may comprise a first adhesive layer 313. The first adhesive layer 313 may couple the protective film 311 and the window 312. The first layer 310 may comprise a second adhesive layer 314. The second adhesive layer 314 may couple the window 312 and the second layer 320.

According to an embodiment of the disclosure, the display device 230 may comprise a second layer 320. The second layer 320 may be coupled to the first layer 310. The second adhesive layer 314 may couple the window 312 and the second layer 320. The second layer 320 may comprise a polarizing layer 321. An upper surface of the polarizing layer 321 may be coupled to the second adhesive layer 314. The second layer 320 may comprise a panel 322. The panel 322 may be coupled to the polarizing layer 321. The second layer 320 may comprise a third adhesive layer 324. The third adhesive layer 324 may couple the polarizing layer 321 and the panel 322. The second layer 320 may comprise an inner film 323. The inner film 323 may be coupled to the panel 322. The second layer 320 may comprise a fourth adhesive layer 325. The fourth adhesive layer 325 may couple the inner film 323 and the reinforcement layer 330. The panel 322 may be named a “flexible display panel.”

According to an embodiment of the disclosure, the display device 230 may comprise a reinforcement layer 330. The reinforcement layer 330 may be disposed between the panel 322 and the digitizer 340. The reinforcement layer 330 may be configured. The reinforcement layer 330 may be configured of a carbon fiber reinforced plastics (CFRP) material. The reinforcement layer 330 may support the panel 322 and may comprise a pattern (e.g., a lattice pattern) in which a plurality of openings or recesses are formed in a central region (e.g., the folding region 233 of FIG. 4) so as to be advantageous for bending. The reinforcement layer 330 may be coupled to the digitizer 340 through a fifth adhesive layer 331.

According to an embodiment of the disclosure, the display device 230 may comprise a digitizer 340. The digitizer 340 may be disposed between the reinforcement layer 330 and the shielding layer 350. The digitizer 340 may detect an electronic pen (not illustrated) (e.g., a stylus pen) outside the electronic device 101 through a method of touch sensing, pressure sensing, or magnetic field detection. For example, the digitizer 340 may detect the movement or contact of an electronic pen (not illustrated) (e.g., a stylus pen) outside the electronic device 101.

According to an embodiment of the disclosure, the digitizer 340 may comprise a first digitizer 341. The digitizer 340 may comprise a second digitizer 342. The first digitizer 341 and the second digitizer 342 may be spaced apart from each other. For example, the first digitizer 341 and the second digitizer 342 may be spaced apart from each other with a folding axis FX (or a folding line) therebetween. The first digitizer 341 may be disposed between at least a portion of a connector 392 and the second digitizer 342. The digitizer 340 may be divided into a first digitizer 341 located adjacent to the connector 392 and a second digitizer 342 located far from the connector 392.

According to an embodiment of the disclosure, the display device 230 may comprise a shielding layer 350. The shielding layer 350 may be disposed between the digitizer 340 and the support layer 360. The shielding layer 350 may be a conductive sheet comprising a magnetic metal powder (MMP). The shielding layer 350 may reduce or limit noise and electromagnetic interference generated from the panel 322 and the digitizer 340.

According to an embodiment of the disclosure, the shielding layer 350 may comprise a first shielding layer 351. The shielding layer 350 may comprise a second shielding layer 352. The first shielding layer 351 and the second shielding layer 352 may be spaced apart from each other with a folding axis FX therebetween. The first shielding layer 351 may be disposed to correspond to the first digitizer 341. The second shielding layer 352 may be disposed to correspond to the second digitizer 342. The first shielding layer 351 may be disposed between at least a portion of the connector 392 and the second shielding layer 352.

According to an embodiment of the disclosure, the display device 230 may comprise a rust-prevention layer 380 that is disposed under the shielding layer 350 to prevent rust of the shielding layer. The rust-prevention layer 380 may be disposed between the shielding layer 350 and the support layer 360. For example, the rust-prevention layer 380 may comprise a first rust-prevention layer 381 adhered to a lower surface of the first shielding layer 351 and a second rust-prevention layer 382 adhered to a lower surface of the second shielding layer 352. The rust-prevention layer 380 may have a structure in which a polyethylene terephthalate film (PET film) is laminated together with a pressure sensitive adhesive (PSA).

According to an embodiment of the disclosure, the display device 230 may comprise a support layer 360. The support layer 360 may be disposed between the shielding layer 350 and the support body 370. The support layer 360 may provide rigidity to the electronic device 101 having a structure that is folded or unfolded. For example, the support layer 360 may support the load of structures (e.g., 310, 320, 330, 340, 350) disposed on an upper side of the support layer 360. For example, the support layer 360 may be at least partially configured of a metal material with high rigidity, thereby reducing or limiting a bending phenomenon (e.g., a distortion phenomenon) occurring in a region adjacent to the folding axis FX of the structures (e.g., 310, 320, 330, 340, 350, 360) when the electronic device 101 is folded or unfolded. The support layer 360 may provide a ground structure to the panel 322 and the digitizer 340.

According to an embodiment of the disclosure, the support layer 360 may comprise a first support layer 361. The support layer 360 may comprise a second support layer 362. The first support layer 361 and the second support layer 362 may be spaced apart from each other. For example, the first support layer 361 and the second support layer 362 may be spaced apart from each other with a folding axis FX therebetween. The first support layer 361 may be disposed between at least a portion of the connector 392 and a folding region S. The support layer 360 may be divided into a first support layer 361 adjacent to the connector 392 and a second support layer 362 located farther from the connector 392 than the first support layer 361. The first support layer 361 and the second support layer 362 may be spaced apart from each other with the folding region S therebetween. The first support layer 361 may be disposed to correspond to the first digitizer 341. The second support layer 362 may be disposed to correspond to the second digitizer 342.

According to an embodiment of the disclosure, the electronic device 101 may comprise a support body 370. The support body 370 may be a portion of a housing (e.g., 210, 220 of FIG. 4), a portion of a hinge assembly (e.g., 202 of FIG. 4), or a separate structure (e.g., a hinge cover) disposed between the hinge assembly and the support layer 360. A portion of the support body 370 located in the folding region S, as a portion of the hinge assembly (e.g., 202 of FIG. 4), may provide a folding axis FX that is a reference about which the electronic device 101 is folded or unfolded. The support body 370 may support structures (e.g., 310, 320, 330, 340, 350, 360) that are folded or unfolded about the folding axis FX.

According to an embodiment of the disclosure, the support body 370 may comprise a first support body 371. The support body 370 may comprise a second support body 372. The first support body 371 and the second support body 372 may be spaced apart from each other with a folding axis FX therebetween. The first support body 371 may be disposed to correspond to the first digitizer 341. The second support body 372 may be disposed to correspond to the second digitizer 342. The first support body 371 may correspond to a first support region (e.g., 212 of FIG. 4) of a first housing (e.g., 210 of FIG. 4) located under the display device 230. The second support body 372 may correspond to a second support region (e.g., 222 of FIG. 4) of a second housing (e.g., 220 of FIG. 4) located under the display device 230.

According to an embodiment of the disclosure, the support body 370 may comprise a first support cover 373. The support body 370 may comprise a second support cover 374. The first support cover 373 may be coupled to the first support body 371. The second support cover 374 may be coupled to the second support body 372. The first support cover 373 and the second support cover 374 may be spaced apart from each other with a folding axis FX therebetween. The first support cover 373 and the second support cover 374 may be located inside the folding region S of the electronic device 101. The first support cover 373 may be a portion (e.g., a wing plate) that is located under the folding region (e.g., 233 of FIG. 4) of the display device 230 and covers one side of the hinge assembly. The second support cover 374 may be a portion (e.g., a wing plate) that is located under the folding region (e.g., 233 of FIG. 4) of the display device 230 and covers the other side of the hinge assembly.

According to an embodiment of the disclosure, the first support layer 361 may be disposed between the first digitizer 341 and the first support body 371. The second support layer 362 may be disposed between the second digitizer 342 and the second support body 372.

According to an embodiment of the disclosure, the display device 230 may comprise a ground member (not illustrated). The ground member may provide a ground structure to the panel 322 or the digitizer 340. A plurality of the ground members may be disposed to be spaced apart from each other. The ground member may be connected to the support layer 360.

According to an embodiment of the disclosure, the display device 230 may comprise a circuit board 391. The circuit board 391 may be an FPCB. The circuit board 391 may be configured of a flexible material. The circuit board 391 may be electrically connected to the panel 322. The circuit board 391 may be electrically connected to the digitizer 340.

According to an embodiment of the disclosure, the electronic device 101 may comprise a connector 392. The connector 392 may be configured of a flexible material. The connector 392 may electrically connect the circuit board 391 and the panel 322. The connector 392 may extend at a position spaced apart from one side of the plurality of layers 320, 330, 350, and 360, and the digitizer 340.

According to an embodiment of the disclosure, the electronic device 101 may comprise a folding axis FX. The folding axis FX may be a reference about which structures of the electronic device 101 including the housings (e.g., 210 and 220 of FIG. 4) are folded or unfolded. A hinge assembly (e.g., 202 of FIG. 4) may provide the folding axis FX of the electronic device 101 (e.g., the display device 230). The folding axis FX may be formed between the first digitizer 341 and the second digitizer 342. The folding axis FX may be formed between the first shielding layer 351 and the second shielding layer 352. The folding axis FX may be formed between the first support layer 361 and the second support layer 362. The folding axis FX may be formed between the first support body 371 and the second support body 372. The folding axis FX may be formed between the first support cover 373 and the second support cover 374. The folding axis FX may be formed between the first inner shielding layer 353 and the second inner shielding layer 354.

According to an embodiment of the disclosure, the electronic device 230 may comprise a folding area S. The folding axis FX may extend through the folding area S. The folding area S may be a space in which the structures of the electronic device 101 including the housings (e.g., 210 and 220 of FIG. 4) are folded or unfolded. The folding area S may be a partial space of the electronic device 101 including the folding axis FX. The folding area S may be formed between the first shielding layer 351 and the second shielding layer 352. The folding area S may be formed between the first support layer 361 and the second support layer 362. The folding area S may be defined as a space formed between the first support layer 361 and the second support layer 362. The first inner shielding layer 353 and the second inner shielding layer 354 may be located within the folding area S. The first support cover 373 and the second support cover 374 may be located within the folding area S.

According to an embodiment of the disclosure, the shielding layer 350 may comprise the first inner shielding layer 353. The first inner shielding layer 353 may be spaced apart from the first shielding layer 351. The first inner shielding layer 353 may be located within the folding area S, and the first shielding layer 351 may be located outside the folding area S. The shielding layer 350 may comprise the second inner shielding layer 354. The second inner shielding layer 354 may be spaced apart from the second shielding layer 352. The second inner shielding layer 354 may be located within the folding area S, and the second shielding layer 352 may be located outside the folding area S.

According to an embodiment of the disclosure, the first support layer 361 and the second support layer 362 may be spaced apart from each other with the folding area S therebetween. The first support layer 361 may be disposed between the connector 392 and the folding area S. The second support layer 362 may be disposed outside the folding area S.

According to an embodiment of the disclosure, the first support layer 361 and the second support layer 362 may be configured to comprise materials corresponding to each other. The display device 230 may comprise driving units 391 and 392. The driving units 391 and 392 may comprise a circuit board 391 and a connector 392. The first support layer 361 may be located adjacent to the driving units 391 and 392, and the second support layer 362 may be located farther from the driving units 391 and 392 than the first support layer 361.

According to an embodiment of the disclosure with reference to FIGS. 6A and 6B, the first support layer 361 may comprise a first support plate 3613 disposed under the digitizer 340 (e.g., the first digitizer 341) and comprising a polymer material, and a first conductive layer 3611 disposed between the digitizer 340 and the first support plate 3613 and plated on a surface of the first support plate 3613. The first support layer 361 may comprise a first bonding layer 3612 (which includes different layers including but not limited to 3612aa, 3612ab, 3612ac, etc.) disposed on the first conductive layer 3611.

According to an embodiment of the disclosure with reference to FIGS. 6A and 6B, the second support layer 362 may comprise a second support plate 3623 disposed under the digitizer 340 (e.g., the second digitizer 342) and comprising a polymer material, and a second conductive layer 3621 (which includes different layers including but not limited to 3621aa, 3621ab, 3621ac, etc.) disposed between the digitizer 340 and the second support plate 3623 and plated on a surface of the second support plate 3623. The second support layer 362 may comprise a second bonding layer 3622 (which includes different layers including but not limited to 3622aa, 3622ab, 3622ac, etc.) disposed on the second conductive layer 3621.

The first conductive layer 3611 and/or the second conductive layer 3621 may be referred to as a conductive layer, and the configuration of the first conductive layer 3611 and the configuration of the second conductive layer 3621 may be identical or similar to each other. The first bonding layer 3612 and/or the second bonding layer 3622 may be referred to as a bonding layer, and the configuration of the first bonding layer 3612 and the configuration of the second bonding layer 3622 may be identical or similar to each other. According to an embodiment of the disclosure, the first support plate 3613 and/or the second support plate 3623 may be referred to as a support plate, and the configuration of the first support plate 3613 and the configuration of the second support plate 3623 may be identical or similar to each other. Hereinafter, the configuration of the first conductive layer 3611, the first bonding layer 3612, and the first support plate 3613 will be described, and the configuration of the second conductive layer 3621, the second bonding layer 3622, and the second support plate 3623 may apply this mutatis mutandis.

According to an embodiment of the disclosure, the first conductive layer 3611 may include a conductive material. The first conductive layer 3611 may comprise copper (Cu). The first conductive layer 3611 may be disposed between the first bonding layer 3612 and the first support plate 3613.

According to an embodiment of the disclosure, the first conductive layer 3611 may be a layer generated by plating a metal on a surface of the non-conductive first support plate 3613 using an electroless plating method. The first conductive layer 3611 may be a Cu-plated layer, and in case that the first support plate 3613 has a thickness of approximately 50 [symbol] , for example, the first conductive layer 3611 may be formed on an upper surface (e.g., one surface in the +Z-axis direction) of the first support plate 3613 to a thickness of approximately 1 [symbol] to 6 [symbol] . For example, the first conductive layer 3611 may be formed on the upper surface (e.g., one surface in the +Z-axis direction) of the first support plate 3613 to a thickness of approximately 6 [symbol] .

According to an embodiment of the disclosure, the first bonding layer 3612 may be disposed between the first shielding layer 351 and the first conductive layer 3611. In the first bonding layer 3612, Ni—P plating and/or a synthetic resin film (PET film) may be attached on the surface of the copper (Cu) for rust prevention of the first conductive layer 3611 comprising the copper (Cu).

According to an example with reference to FIG. 6A, the first bonding layer 3612 may comprise a layer 3612aa in which a PET film (polyethylene terephthalate film) is laminated together with a pressure sensitive adhesive (PSA), and may be disposed on a copper (Cu) surface (e.g., the surface of the first conductive layer 3611) for rust prevention. According to an embodiment of the disclosure, the first bonding layer 3612 may comprise a coating layer 3612ab that is disposed on the layer 3612aa in which the pressure sensitive adhesive and the PET film are laminated and applies a pressure sensitive adhesive for additional rust prevention such that the copper (Cu) and/or the shielding layer 350 (e.g., magnetic metal powder (MMP)) does not rust. For example, in case that the first bonding layer 3612 is formed of the pressure sensitive adhesive and the PET film, on the first support plate 3613 having a thickness of approximately 50 [symbol] and the first conductive layer 3611 plated to a thickness of approximately 6 [symbol] , the layer 3612aa in which the pressure sensitive adhesive and the PET film of the first bonding layer 3612 are laminated may be formed to a thickness of approximately 6 [symbol] (3 [symbol] +3 [symbol] ), and the coating layer 3612ab may be formed to a thickness of approximately 50 [symbol] . According to an example with reference to FIG. 6B, the first bonding layer 3612 may comprise a Ni—P plating layer 3612ac formed on a copper (Cu) surface (e.g., the surface of the first conductive layer 3611) for rust prevention. According to an embodiment of the disclosure, the first bonding layer 3612 may comprise a coating layer 3612ab that is disposed on the Ni—P plating layer 3612ac and applies a pressure sensitive adhesive for additional rust prevention such that the copper (Cu) and/or the shielding layer 350 (e.g., magnetic metal powder (MMP)) does not rust. For example, in case that the first bonding layer 3612 is formed of the pressure sensitive adhesive and the Ni—P plating layer, on the first support plate 3613 having a thickness of approximately 50 [symbol] and the first conductive layer 3611 plated to a thickness of approximately 6 [symbol] , the Ni—P plating layer 3612ac of the first bonding layer 3612 may be formed to a thickness of approximately 1 [symbol] , and the coating layer 3612ab may be formed to a thickness of approximately 50 [symbol] .

According to an embodiment of the disclosure, the first support plate 3613 may include a non-conductive material. According to an embodiment of the disclosure, the first support plate 3613 may include a composite polymer material. For example, the first support plate 3613 comprises a polymer composite material reinforced with a filler material, and may be at least one of carbon fiber reinforced plastics (CFRP) or glass fiber reinforced plastics (GFRP). The first support plate 3613 may be disposed between the first conductive layer 3611 and the first support body 371. The first support plate 3613 may be disposed between the first conductive layer 3611 and the circuit board 391.

According to an embodiment of the disclosure, the first support plate 3613 includes a composite polymer material, rather than the stainless steel (SUS) generally used to support the respective layers of a display device, and thus may provide weight reduction of the display device 230. For example, the density of carbon fiber reinforced plastics (CFRP), which is one of the materials of the first support plate 3613, is 1.6 g/cm³, which is approximately 20 to 25% of the density of SUS (7.9 g/cm³), and thus may provide weight reduction of the component. When the thickness of the material is based on approximately 50 [symbol] , compared with the weight of SUS being approximately 4 g, the weight of the CFRP of the disclosure may be approximately 0.8 g. For example, the density of glass fiber reinforced plastics (GFRP), which is one of the materials of the first support plate 3613, is 2.3 g/cm³, which is approximately 25 to 30% of the density of SUS (7.9 g/cm³), and thus may provide weight reduction of the component. When the thickness of the material is based on approximately 50 [symbol] , compared with the weight of SUS being approximately 4 g, the weight of the CFRP of the disclosure may be approximately 1.0 g.

According to an embodiment of the disclosure, the first support plate 3613 includes a composite polymer material, rather than the stainless steel (SUS) generally used to support the respective layers of a display device, and thus may provide weight reduction of the display device 230 together with enhanced tensile strength. For example, the tensile strength of carbon fiber reinforced plastics (CFRP), which is one of the materials of the first support plate 3613, is 2860 MPa (T700), which may be confirmed to be a large value compared with the tensile strength of SUS (500 MPa). For example, the tensile strength of glass fiber reinforced plastics (GFRP), which is one of the materials of the first support plate 3613, is 250 to 950 MPa, which may be confirmed to be able to have a value similar to or larger than the tensile strength of SUS (500 MPa).

According to an embodiment of the disclosure, the first support plate 3613 includes a composite polymer material, rather than the stainless steel (SUS) generally used to support the respective layers of a display device, and thus may provide enhanced elasticity to the display device 230, which may be advantageous for flexibility (or bending). For example, the elastic modulus of carbon fiber reinforced plastics (CFRP), which is one of the materials of the first support plate 3613, is 134 GPa (T700), which may be confirmed to be a small value compared with the elastic modulus of SUS (180 GPa). For example, the elastic modulus of glass fiber reinforced plastics (GFRP), which is one of the materials of the first support plate 3613, is 10 to 40 GPa, which may be confirmed to be a small value compared with the elastic modulus of SUS (180 GPa). According to an embodiment of the disclosure, as the first support layer 361 plates a conductive material (e.g., copper (Cu)) on the surface of the first support plate 3613 (e.g., the first conductive layer 3611), the overall thickness may be reduced together with enhancement of the bending rigidity of the display device 230. In a general display device, a Cu film is attached and used on stainless steel (SUS), and in this case, a thick adhesive (e.g., an adhesive film of at least 50 [symbol] (e.g., a pressure sensitive adhesive)) is required for the attachment, and an additional PET film attachment is required to prevent oxidation of the Cu film. In contrast, the display device 230 of the disclosure directly plates copper (Cu) on the surface of the first support plate 3613, such that only a thickness of approximately 6 [symbol] or less and a weight of approximately 0.8 g are applied during Cu plating, which, compared with a Cu film (a thickness of approximately 12 [symbol] and approximately 1.4 g), may provide a significant thickness reduction and weight reduction effect. For example, even when comparing the overall thickness of the laminated structure under the digitizer 340, compared with the thickness and weight of a general structure (a thickness of 125 [symbol] and a weight of 5.4 g), the thickness and weight of the structure of the disclosure (the thickness is approximately 106 [symbol] , and the weight is approximately 1.6 g (e.g., approximately 1.3 g to 2.0 g)) may be reduced, which may provide weight reduction and thickness reduction of the electronic device.

FIG. 7A is an enlarged view illustrating an enlargement of a portion P of a structure of a display device according to an embodiment of the disclosure.

FIG. 7B is an enlarged view illustrating an enlargement of a portion P of a structure of a display device according to an embodiment of the disclosure.

According to an embodiment of the disclosure, the electronic device (e.g., the electronic device 101 of FIGS. 1 to 4) may comprise a flexible display device 230.

The configuration of the flexible display device 230 of FIGS. 7A and 7B may be identical in part or whole to the configuration of the display module 160 of FIG. 1 and/or the configuration of the display device 230 of FIGS. 2 to 5, 6A, and 6B. The embodiment of FIGS. 7A and 7B may be selectively combined with the embodiments of FIGS. 5, 6A, 6B, and 8 to 10.

According to an embodiment of the disclosure, the display device 230 comprises a structure in which the digitizer 340, the shielding layer 350, and the support layer 360 are sequentially laminated, and the support layer 360 may comprise the first support layer 361 and the second support layer 362. Each of the first support layer 361 and the second support layer 362 may comprise a support plate 3613 and 3623, a conductive layer 3611 and 3612, and a bonding layer 3612 and 3622. Hereinafter, the description will focus on a specific configuration of the support layer that is different from FIGS. 6A and 6B.

According to an embodiment of the disclosure, the support layer 360 of the display device 230 may be disposed under the digitizer 340 and the shielding layer 350. The support layer 360 may provide rigidity to the electronic device 101 having a structure that is folded or unfolded. For example, the support layer 360 may support the load of the structures (e.g., the digitizer 340 and the shielding layer 350) disposed on the upper side of the support layer 360. For example, at least a part of the support layer 360 includes a metal material having high rigidity, such that, when the electronic device 101 is folded or unfolded, the support layer 360 may reduce or limit a bending phenomenon (e.g., a deforming phenomenon) of the structures occurring in an area adjacent to the folding axis FX.

According to an embodiment of the disclosure, the support layer 360 may comprise the first support layer 361. The support layer 360 may comprise the second support layer 362. The first support layer 361 and the second support layer 362 may be spaced apart from each other. For example, the first support layer 361 and the second support layer 362 may be spaced apart from each other with the folding axis FX therebetween.

According to an embodiment of the disclosure, the first support layer 361 may be disposed between the first digitizer 341 and the first support body 371. The second support layer 362 may be disposed between the second digitizer 342 and the second support body 372.

According to an embodiment of the disclosure, the first support layer 361 may comprise a first support plate 3613 disposed under the first digitizer 341 and comprising a polymer material, a first-first conductive layer 3611a plated on an upper surface of the first digitizer 341, and a first-second conductive layer 3611b plated on a lower surface of the first digitizer 341. The first support layer 361 may comprise a first-first bonding layer 3612a disposed on the first-first conductive layer 3611a. The first support layer 361 may comprise a first-second bonding layer 3612b disposed on (e.g., a lower surface of) the first-second conductive layer 3611b.

According to an embodiment of the disclosure, the second support layer 362 may comprise a second support plate 3623 disposed under the second digitizer 342 and comprising a polymer material, a second-first conductive layer 3621a plated on an upper surface of the second digitizer 342, and a second-second conductive layer 3621b plated on a lower surface of the second digitizer 342. The second support layer 362 may comprise a second-first bonding layer 3622a disposed on the second-first conductive layer 3621a. The second support layer 361 may comprise a second-second bonding layer 3622b disposed on (e.g., a lower surface of) the second-second conductive layer 3621b. Hereinafter, a specific laminated structure for the first support layer 361 will be described, and the configuration of the second support layer 362 may apply the configuration of the first support layer 361 mutatis mutandis.

According to an embodiment of the disclosure, the first conductive layer 3611 may include a conductive material. The first conductive layer 3611 may comprise a first-first conductive layer 3611a and a first-second conductive layer 3611b disposed on the upper and lower surfaces of the first support plate 3613. The first conductive layer 3611 may comprise copper (Cu). In the first conductive layer 3611, Ni—P plating and/or a synthetic resin film (PET film) may be attached on the surface of the copper (Cu) for rust prevention of the copper (Cu).

According to an embodiment of the disclosure, the first-first conductive layer 3611a may be disposed between the first-first bonding layer 3612a and the first support plate 3613. The first-second conductive layer 3611b may be disposed between the first-second bonding layer 3612b and the first support plate 3613. The first conductive layer 3611 may be a layer generated by plating a metal on each of the upper and lower surfaces of the non-conductive first support plate 3613 using an electroless plating method. The first-first conductive layer 3611a and the first-second conductive layer 3611b may be Cu-plated layers, and in case that the first support plate 3613 has a thickness of approximately 50 [symbol] , for example, the first-first conductive layer 3611a and the first-second conductive layer 3611b have a thickness of approximately 1 [symbol] to 6 [symbol] on each of the upper and lower surfaces of the first support plate 3613, and may form a total thickness of 2 [symbol] to 12 [symbol] . For example, the first-first conductive layer 3611a and the first-second conductive layer 3611b have a thickness of approximately 1 [symbol] to 3 [symbol] on each of the upper and lower surfaces of the first support plate 3613, and may form a total thickness of 2 [symbol] to 6 [symbol] .

According to an embodiment of the disclosure, a 1-1th bonding layer 3612a may be disposed between a first shielding layer 351 and a 1-1th conductive layer 3611a. As for the first bonding layer 3612a, Ni—P plating and/or a synthetic resin film (PET film) may be attached on the copper (Cu) surface for rust prevention of the 1-1th conductive layer 3611a comprising copper (Cu).

According to an example with reference to FIG. 7A, the first bonding layer 3612a comprises a layer 3612aa in which a polyethylene terephthalate film (PET film) is laminated together with a pressure sensitive adhesive (PSA), and may be disposed on the copper (Cu) surface (e.g., the surface of the 1-1th conductive layer 3611a) for rust prevention. According to an embodiment of the disclosure, the first bonding layer 3612a may comprise a coating layer 3612ab which is disposed on the layer 3612aa in which the pressure sensitive adhesive and the PET film are laminated and applies a pressure sensitive adhesive for additional rust prevention such that the copper (Cu) and/or the shielding layer 350 (e.g., magnetic metal powder (MMP)) does not rust. According to an embodiment of the disclosure, a 1-2th bonding layer 3612b may be disposed between a first support body 371 and a 1-2th conductive layer 3611b. For example, the 1-2th bonding layer 3612b may be a structure in which a polyethylene terephthalate film (PET film) is laminated together with a pressure sensitive adhesive.

According to an embodiment of the disclosure, the 1-1th bonding layer 3612a is positioned more adjacent to a digitizer 340 than the 1-2th bonding layer 3612b, and accordingly may have a greater thickness. For example, in case that the 1-1th bonding layer 3612a is formed of a pressure sensitive adhesive (PSA) and a PET film, on a first support plate 3613 having a thickness of approximately 50 [symbol] and the 1-1th conductive layer 3611a plated to a thickness of approximately 3 [symbol] , the layer 3612aa in which the pressure sensitive adhesive and the PET film of the 1-1th bonding layer 3612a are laminated may be formed to a thickness of approximately 6 [symbol] (3 [symbol] +3 [symbol] ), and the coating layer 3612ab may be formed to a thickness of approximately 50 [symbol] . For example, in case that the 1-2th bonding layer 3612b is formed of a laminated structure of a pressure sensitive adhesive (PSA) and a polyethylene terephthalate film (PET film), on the first support plate 3613 having a thickness of approximately 50 [symbol] and the 1-2th conductive layer 3611b plated to a thickness of approximately 3 [symbol] (e.g., the lower surface), the 1-2th bonding layer 3612b may be formed to a total thickness of 6 [symbol] , which is the sum of approximately 3 [symbol] of the pressure sensitive adhesive (PSA) and approximately 3 [symbol] of the polyethylene terephthalate film (PET film).

According to an example with reference to FIG. 7B, the 1-1th bonding layer 3612a may comprise a Ni—P plating layer 3612ac formed on the copper (Cu) surface (e.g., the surface of the 1-1th conductive layer 3611a) for rust prevention. According to an embodiment of the disclosure, the 1-1th bonding layer 3612a may comprise a coating layer 3612ab which is disposed on the Ni—P plating layer 3612ac and applies a pressure sensitive adhesive for additional rust prevention such that the copper (Cu) and/or the shielding layer 350 (e.g., magnetic metal powder (MMP)) does not rust. According to an embodiment of the disclosure, the 1-2th bonding layer 3612b may be disposed between the first support body 371 and the 1-2th conductive layer 3611b. For example, the 1-2th bonding layer 3612b may comprise a Ni—P plating layer 3612ac formed on the copper (Cu) surface (e.g., the lower surface of the 1-2th conductive layer 3611b) for rust prevention. For example, in case that the 1-1th bonding layer 3612a is formed of a pressure sensitive adhesive and a Ni—P plating layer, on the upper surface of the first support plate 3613 having a thickness of approximately 50 [symbol] and the 1-1th conductive layer 3611a plated to a thickness of approximately 3 [symbol] , the Ni—P plating layer 3612ac of the 1-1th bonding layer 3612a may be formed to a thickness of approximately 1 [symbol] , and the coating layer 3612ab may be formed to a thickness of approximately 50 [symbol] . For example, in case that the 1-2th bonding layer 3612b is formed of a Ni—P plating layer, on the lower surface of the first support plate 3613 having a thickness of approximately 50 [symbol] and the 1-2th conductive layer 3611b plated to a thickness of approximately 3 [symbol] , the Ni—P plating layer 3612ac of the 1-2th bonding layer 3612b may be formed to a thickness of approximately 1 [symbol] .

According to an embodiment of the disclosure, the first support plate 3613 may include a non-conductive material. According to an embodiment of the disclosure, the first support plate 3613 may include a composite polymer material. For example, the first support plate 3613 is a polymer composite material reinforced with a filler material, and may be at least one of carbon fiber reinforced plastics (CFRP) or glass fiber reinforced plastics (GFRP). The first support plate 3613 may be disposed between a first conductive layer 3611 and the first support body 371. The first support plate 3613 may be disposed between the first conductive layer 3611 and a circuit board 391.

According to an embodiment of the disclosure, since the first support plate 3613 includes a composite polymer material, it may provide weight reduction of a display device 230 compared to commonly used stainless steel (SUS). For example, the density of carbon fiber reinforced plastics (CFRP), which is one of the materials of the first support plate 3613, is 1.6 g/cm³, which may provide weight reduction of the component at a level of approximately 20 to 25% compared to the density of SUS (7.9 g/cm³). When the thickness of the material is based on approximately 50 [symbol] , compared to the weight of SUS being approximately 4 g, the weight of the CFRP of the disclosure may be approximately 0.8 g. For example, the density of glass fiber reinforced plastics (GFRP), which is one of the materials of the first support plate 3613, is 2.3 g/cm³, which may provide weight reduction of the component at a level of approximately 25 to 30% compared to the density of SUS (7.9 g/cm³). When the thickness of the material is based on approximately 50 [symbol] , compared to the weight of SUS being approximately 4 g, the weight of the CFRP of the disclosure may be approximately 1.0 g.

According to an embodiment of the disclosure, a first support layer 361 plates a conductive material (e.g., copper (Cu)) on the upper and lower surfaces of the first support plate 3613 (e.g., the 1-1th conductive layer 3611a and the 1-2th conductive layer 3611b), and accordingly may reduce the overall thickness together with reinforcing the bending stiffness of the display device 230. In a general display device, a Cu film is attached on stainless steel (SUS) and used, and in this case, a thick adhesive (e.g., an adhesive film of at least 50 [symbol] (e.g., a pressure sensitive adhesive)) is required for the attachment, and an additional PET film attachment is required to prevent oxidation of the Cu film. In contrast, the display device 230 of the disclosure directly plates copper (Cu) on each of the upper and lower surfaces of the first support plate 3613, such that only a total thickness of approximately 6 [symbol] and a weight of approximately 0.8 g are applied during the Cu plating, which may provide a remarkable thickness reduction and weight reduction effect compared to the Cu film (a thickness of approximately 12 [symbol] , approximately 1.4 g). For example, even when comparing the overall thickness of the laminated structure below the digitizer 340, compared to the thickness and weight of a general structure (a thickness of 125 [symbol] , a weight of 5.4 g), the thickness and weight of the structure of the disclosure (a thickness of approximately 106 [symbol] , a weight of approximately 1.6 g (e.g., approximately 1.3 g to 2.0 g)) may be reduced, which may provide weight reduction and thickness reduction of the electronic device.

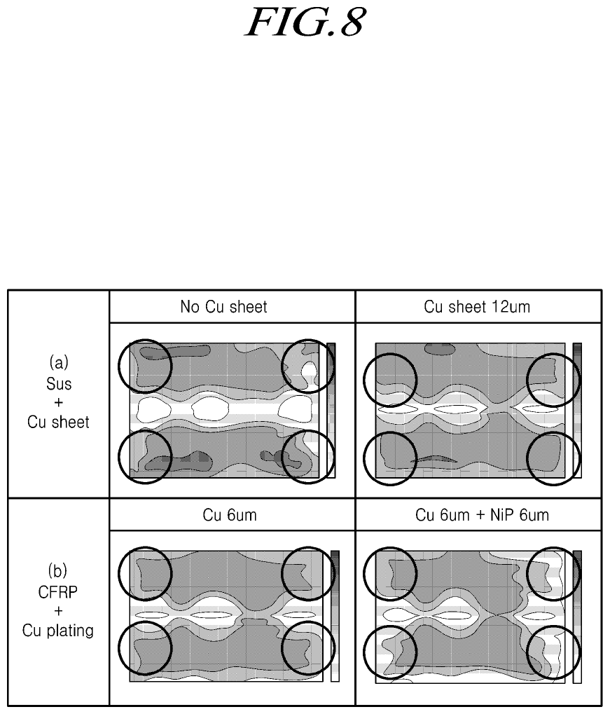

FIG. 8 is a view illustrating a result of 2D scanning a support layer structure disposed below a digitizer among a general display device and a display device 230 according to an embodiment of the disclosure.

According to an embodiment of the disclosure, an electronic device (e.g., an electronic device 101 of FIGS. 1 to 4) may comprise a flexible display device (e.g., 230 of FIGS. 5, 6A, 6B, 7A, and 7B).

The configuration of the flexible display device of FIG. 8 may be identical in whole or part to the configuration of a display module 160 of FIG. 1 and/or the display device 230 of FIGS. 2 to 5, 6A, and 6B. The embodiment of FIG. 8 may be selectively combined with the embodiments of FIGS. 5 to 6A, 6B, 7A and 7B and FIGS. 9 and 10.

According to an embodiment of the disclosure, the display device 230 may comprise a first layer (e.g., 310 of FIG. 5), a second layer (e.g., 320 of FIG. 5), a reinforcement layer (e.g., 330 of FIG. 5), a digitizer (e.g., 340 of FIG. 5), a shielding layer (e.g., 350 of FIG. 5), and a support layer (e.g., 360 of FIG. 5). A support layer 360 may provide a structure laminated together with the digitizer 340 and the shielding layer 350. The support layer 360 may comprise a support plate and a conductive layer plated on the surface of the support plate.

Referring to part (a) of FIG. 8, provided is a view illustrating a result of 2D scanning a support layer of a general display device, wherein the support layer includes only stainless steel (SUS), or is a configuration in which stainless steel (SUS) and a Cu sheet (or a Cu film) disposed on the stainless steel are provided. The left view of part (a) of FIG. 8 is a 2D scan of a structure in which a Cu sheet is not disposed, and the right view of part (a) of FIG. 8 is a 2D scan of a structure in which a Cu sheet is disposed on the stainless steel.

Referring to part (b) of FIG. 8, provided is a view illustrating a result of 2D scanning the support layer 360 of the display device 230 of the disclosure, wherein the support layer 360 is a structure in which a conductive layer is plated on the surface of a support plate. The support plate may be at least one of carbon fiber reinforced plastics (CFRP) or glass fiber reinforced plastics (GFRP). The conductive layer may be a layer generated by plating Cu to approximately 6 [symbol] on the upper surface of the CFRP or GFRP, or a layer generated by plating Cu by 3 [symbol] each on the upper surface and the lower surface of the CFRP or GFRP. The left view of part (b) of FIG. 8 is a 2D scan of a structure in which the plating layer is processed with only Cu plating, and the right view of part (b) of FIG. 8 is a 2D scan of a structure in which Ni/P plating is additionally performed in addition to the Cu plating.

Comparing part (a) of FIG. 8 and part (b) of FIG. 8, it may be confirmed that, when Cu is plated on the surface of a base material (e.g., CFRP or GFRP) rather than simply disposing a Cu sheet on a base material (e.g., SUS), the bending stiffness of the display device 230 may be reinforced, and accordingly the support layer 360 of the disclosure is suitable as a plate for reinforcing the stiffness of a flexible display panel. In case that the support layer stiffness is insufficient, in the result of the 2D scan, a portion of a housing on the rear surface of the flexible display device (e.g., a die casting injection portion) may be visually recognized. The portion of the housing (e.g., the die casting injection portion) is a portion indicated by a circle, and whether it is visually recognized may be confirmed depending on whether the portions indicated by the circle have the same/similar values (e.g., similar colors) to each other. For example, it may be understood that, if the portions indicated by the circle have different values from each other, visual recognition is possible, and if the portions indicated by the circle have the same/similar values to each other, visual recognition is difficult.

The left view of part (a) of FIG. 8 is a structure in which the support layer is made of only stainless steel (SUS), and it may be confirmed that, since the portions indicated by the circle have different values from each other, the colors differ. This indicates that a portion of the housing (e.g., a die casting injection portion) is visually recognized, and it may be considered that this is unsuitable as a component because the stiffness of the support layer is insufficient.

The right view of part (a) of FIG. 8 is a structure in which a Cu sheet having a thickness of 12 [symbol] is disposed on stainless steel (SUS), and it may be confirmed that, since the portions indicated by the circle have the same/similar values to each other, the colors are also the same/similar. It may be confirmed that, in general, in order for a portion of the housing (e.g., a die casting injection portion) not to be visually recognized, a Cu sheet having a minimum thickness of 12 [symbol] is required.

The left view of part (b) of FIG. 8 is a structure in which Cu having a thickness of 6 [symbol] is plated on (or on and below) the support plate (CFRP or GFRP) of the support layer 360, and it may be confirmed that, since the portions indicated by the circle have the same/similar values to each other, the colors are also the same/similar. It may be confirmed that, in order for a portion of the housing (e.g., a die casting injection portion) not to be visually recognized, Cu plating having a minimum thickness of 6 [symbol] is required. It may be confirmed that, compared to a general structure (e.g., the right figure of part (a) of FIG. 8), the structure of the support layer of the disclosure uses Cu of a small thickness to provide sufficient bending stiffness, and accordingly provides overall weight reduction and thickness reduction of the electronic device.

The right figure of part (b) of FIG. 8 is a structure in which Cu plating having a thickness of 6 [symbol] and Ni/P plating are performed on (or on and below) the support plate (CFRP or GFRP) of the support layer, and it may be confirmed that, since the portions indicated by the circle have the same/similar values to each other, the colors are also the same/similar. It may be confirmed that the right figure of part (b) of FIG. 8, compared to the right figure of part (a) of FIG. 8 and the left figure of part (b), has more identical values in the portions indicated by the circle. It may be confirmed that, compared to a general structure (e.g., the right figure of part (a) of FIG. 8), the structure of the support layer of the disclosure uses Cu of a small thickness to provide sufficient bending stiffness, and accordingly provides overall weight reduction and thickness reduction of the electronic device.

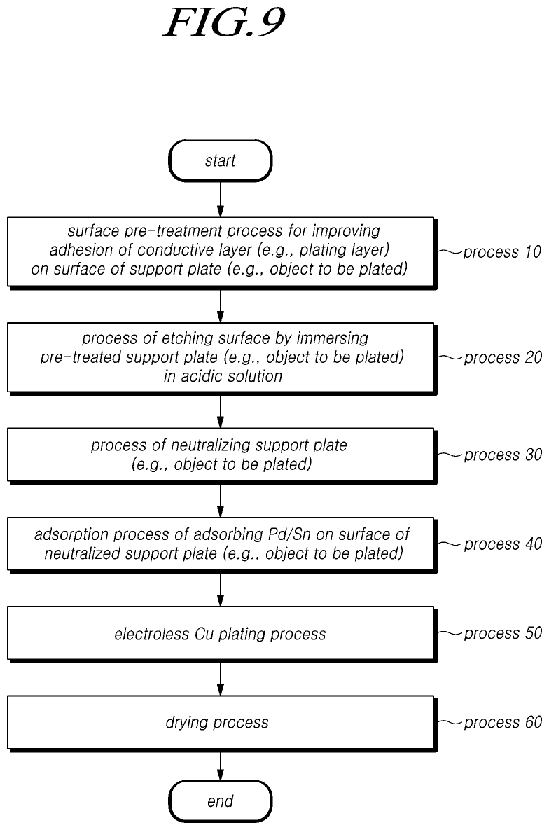

FIG. 9 is a flowchart illustrating a surface plating process on a support plate of a support layer according to an embodiment of the disclosure.

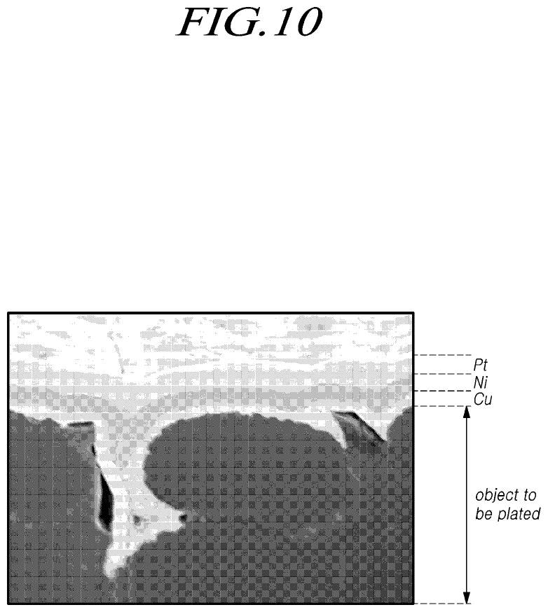

FIG. 10 is a view illustrating a cross-section of a support layer after a surface plating process of the flowchart of FIG. 9 according to an embodiment of the disclosure.

According to an embodiment of the disclosure, an electronic device (e.g., the electronic device 101 of FIGS. 1 to 4) may comprise a flexible display device 230. The display device 230 may comprise a first layer (e.g., 310 of FIG. 5), a second layer (e.g., 320 of FIG. 5), a reinforcement layer (e.g., 330 of FIG. 5), a digitizer (e.g., 340 of FIG. 5), a shielding layer (e.g., 350 of FIG. 5), and a support layer (e.g., 360 of FIG. 5). The support layer 360 may provide a structure laminated together with the digitizer 340 and the shielding layer 350. The support layer 360 may comprise a support plate and a conductive layer plated on the surface of the support plate.

The configuration of the support layer of the flexible display device 230 of FIGS. 9 and 10 may be identical in whole or part to the configuration of the support layer of FIGS. 5, 6A, 6B, 7A, 7B, and 8. The embodiment of FIG. 10 may be selectively combined with the embodiments of FIGS. 5, 6A, 6B, 7A, 7B, and 8, and FIGS. 11A and 11B.

According to an embodiment of the disclosure, the support layer 360 may be a structure in which a conductive layer is plated on (or on and below) a support plate. According to an embodiment of the disclosure, the support plate may be at least one of carbon fiber reinforced plastics (CFRP) or glass fiber reinforced plastics (GFRP). According to an embodiment of the disclosure, the conductive layer may be a layer generated by plating Cu to approximately 6 [symbol] on the upper surface of the CFRP or GFRP, or a layer generated by plating Cu by 3 [symbol] each on the upper surface and the lower surface of the CFRP or GFRP. According to an embodiment of the disclosure, the conductive layer may be a layer generated by, after plating Cu on the surface of the CFRP or GFRP, additionally performing Ni/P plating.

Referring to FIG. 9, first, a surface pre-processing process (process 10) for improving the adhesion of a conductive layer (e.g., a plating layer) on the surface of a support plate (e.g., an object to be plated) may be performed. The pre-processing process may be referred to as a cleaner process. For example, the pre-processing process may be performed to remove foreign substances adhering during molding of the object to be plated including one material among polymer composite materials (CFRP, GFRP), thereby densely adjusting the surface of the object to be plated during electroless plating and improving the adhesion of the plating layer.

The support plate (e.g., the object to be plated) is immersed in a cleaner treatment liquid at a temperature of approximately 20 °C to 50 °C for approximately 30 seconds to 5 minutes and then washed with water, whereby unnecessary dust adhering to the object to be plated may be removed. The cleaner treatment liquid may include 5 to 10 parts by weight of sodium bisulfite, 85 to 90 parts by weight of pure water, 1 to 5 parts by weight of sulfuric acid (H2SO4), and other non-hazardous substances.

Thereafter, a process (process 20) of immersing the pre-processed support plate (e.g., the object to be plated) in an acidic solution to etch the surface may be performed. The etching process may immerse the object to be plated in a mixed solution containing a strong acid, such as phosphoric acid to etch the surface of the object to be plated (e.g., the upper surface, or the upper/lower surfaces). The etching process may be performed at room temperature or a high temperature (approximately 75 °C) for approximately 5 to 10 minutes (min). For example, the etching process may be performed at room temperature for approximately 5 to 9 minutes (min). The etching process may be a process for facilitating an adsorption process (process 40) performed thereafter.

Thereafter, a process (process 30) of neutralizing the support plate (e.g., the object to be plated) may be performed. The neutralization process may be a process of neutralizing the support plate (e.g., the object to be plated) that has undergone the etching process in an aqueous hydrochloric acid solution at room temperature for several minutes and then washing it with water.

Thereafter, an adsorption process (process 40) of adsorbing Pd/Sn on the surface of the neutralized support plate (e.g., the object to be plated) may be performed. The Pd/Sn adsorption may be a catalytic process for increasing the surface adhesion of an electroless Cu plating layer. For example, a Pd/Sn colloid may be adsorbed on the surface of the object to be plated (CFRP, GFRP) and perform a catalytic role in a subsequent plating process. In case that the amount of the Pd/Sn colloid adsorbed on the surface of a non-conductive material, such as plastic increases, thereafter, a uniform and good conductive film may be formed on the non-conductive material (e.g., the object to be plated) in the plating process.

Thereafter, an electroless Cu plating process (process 50) may be performed. Cu plating through an oxidation-reduction reaction may be performed on the Pd adsorbed on a surface of the support plate (e.g., the object to be plated). Referring to FIG. 10, through the electroless Cu plating process, Cu may penetrate into the object to be plated and form a film while maintaining a strong bond with the object to be plated.

Thereafter, when a drying process (process 60) is performed, the support layer may be completed.

According to an embodiment of the disclosure, after the electroless Cu plating process (process 50) and before the drying process (process 60), a Ni/P plating process may be additionally performed. The Ni/P plating process may proceed as an electroless process similar to the electroless Cu plating process. The Ni/P plating process may be a process for rust prevention of the plated Cu layer. After the Ni/P plating process is performed, the support layer 360 may provide improved flexural rigidity of the support layer, as identified in the right figure of part (b) of FIG. 8 and in FIG. 10. The Pt in FIG. 10 may be understood as a layer sputtered to confirm surface quality using a scanning electron microscope (SEM).

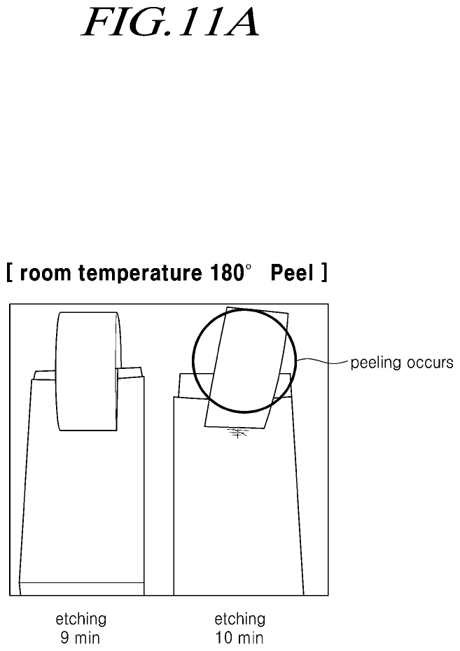

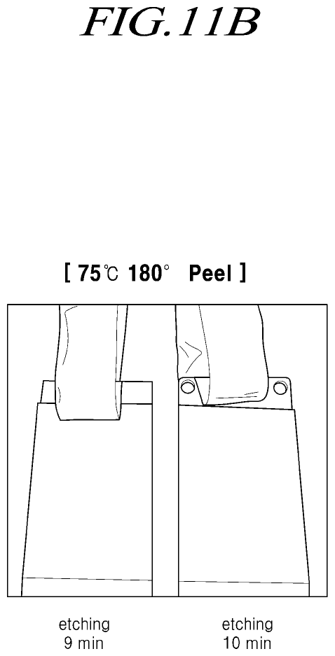

FIG. 11A is a view illustrating a result of a peel test at room temperature, considering rework of the display device, according to an embodiment of the disclosure.

FIG. 11B is a view illustrating a result of a peel test at a high temperature (e.g., approximately 75 °C), considering rework of the display device, according to an embodiment of the disclosure.

According to an embodiment of the disclosure, an electronic device (e.g., the electronic device 101 of FIGS. 1 to 4) may comprise a flexible display device (e.g., 230 of FIGS. 5 to 7B). The display device 230 may comprise a first layer (e.g., 310 of FIG. 5), a second layer (e.g., 320 of FIG. 5), a reinforcement layer (e.g., 330 of FIG. 5), a digitizer (e.g., 340 of FIG. 5), a shielding layer (e.g., 350 of FIG. 5), and a support layer (e.g., 360 of FIG. 5). The support layer 360 may provide a structure stacked together with the digitizer 340 and the shielding layer 350. The support layer 360 may comprise a support plate and a conductive layer plated on a surface of the support plate.

The configuration of the support layer of the flexible display device 230 of FIGS. 11A and 11B (e.g., the figure of etching for 9 minutes (min)) may be identical in whole or in part to the configuration of the support layer of FIGS. 5 to 10. The embodiment of FIGS. 11A and 11B may be selectively combined with the embodiments of FIGS. 5, 6A, 6B, 7A, 7B, 8, and 9.

The electronic device 101 may proceed with rework to check the performance of or repair a component (e.g., the display device 230), and may check in advance a result of the rework through a peel test before a finished product. The peel test may be referred to as a surface adhesive tape peel test or a repairability test.

TABLE 1

| | | #1 | #2 |
|---|---|---|---|
| | | CFRP | CFRP |
| Sample | | etching 9 min | etching 10 min |
| 180° PEEL | Room | 2330 | 2220 (surface |
| (gf/25 mm) | temperature | | peeling) |
| | 75 °C | 950 | 1010 |

Table 1 is a table illustrating the results of a peel test performed at room temperature and a high temperature (e.g., approximately 75 °C), respectively, on an experimental example (#1) subjected to etching treatment for 9 minutes (min) and an experimental example (#2) subjected to etching treatment for 10 minutes (min). The peel test, referring to FIG. 5, was conducted as a test for separating the shielding layer 350 and the support layer 360 in the display device 230.

Referring to Table 1 and the left figure of FIG. 11A, considering the experimental example (#1) subjected to etching treatment for 9 minutes (min), as a result of the peel test conducted at room temperature, no tearing of the conductive layer (e.g., 3611 of FIGS. 6A, 6B, 7A, and 7B) plated on the surface on the support plate (e.g., 3613 of FIGS. 6A, 6B, 7A, and 7B) occurred, and thus it may be confirmed that the plating treatment proceeded well (e.g., passing the peel test).

Referring to Table 1 and the left figure of FIG. 11B, considering the experimental example (#1) subjected to etching treatment for 9 minutes (min), as a result of the peel test conducted at a high temperature (e.g., approximately 75 °C), no tearing of the conductive layer (e.g., 3611 of FIGS. 6A, 6B, 7A, and 7B) plated on the surface on the support plate (e.g., 3613 of FIGS. 6A, 6B, 7A, and 7B) occurred, and thus it may be confirmed that the plating treatment proceeded well (e.g., passing the peel test).

Referring to Table 1 and the right figure of FIG. 11A, considering the experimental example (#2) subjected to etching treatment for 10 minutes (min), as a result of the peel test conducted at room temperature, tearing of the conductive layer plated on the surface on the support plate occurred, and thus it may be confirmed that the plating treatment did not proceed well (e.g., failing to pass the peel test).

Referring to Table 1 and the right figure of FIG. 11B, considering the experimental example (#2) subjected to etching treatment for 10 minutes (min), as a result of the peel test conducted at a high temperature (e.g., approximately 75 °C), no tearing of the conductive layer plated on the surface on the support plate occurred, and thus it may be confirmed that the plating treatment proceeded well (e.g., passing the peel test).

In general, when rework is performed, it may be considered that processing at room temperature rather than at a high temperature does not damage other components of the electronic device and that the processing is easier. Considering the result of the peel test accordingly, it may be confirmed that the sample of the experimental example (#1) subjected to etching treatment for 9 minutes (min) has good adhesion and is a structure that passed the peel test without tearing of the plating layer (e.g., the conductive layer) occurring.

The display device of an electronic device according to an embodiment of the disclosure may improve the material and structure of the support layer disposed under the digitizer, thereby providing weight reduction and thinning of the display device.

The support layer of a display device according to an embodiment of the disclosure may provide weight reduction of the display device by configuring a structure of the support plate that supports the digitizer with a low-density polymer composite material compared with metal (e.g., SUS).

The support layer of a display device according to an embodiment of the disclosure may be formed by plating a conductive layer for flattening the electric field and the magnetic field of the digitizer on a surface of the support plate. Accordingly, the conductive layer may provide a thickness thinner than the thickness of a metal film (e.g., a Cu film) that has been generally used, and may reduce the thickness of an adhesive used for attaching the metal film. Further, the display device may provide weight reduction according to the reduction in thickness.

Effects obtainable from the disclosure are not limited to the above-mentioned effects, and other effects not mentioned will be clearly understood by those of ordinary skill in the art to which the disclosure pertains from the following description.

An electronic device (e.g., 101 of FIG. 1) according to an embodiment of the disclosure may comprise a first housing 210, a second housing 220, and a display device 230 disposed on the first housing and the second housing. The display device 230 may comprise a flexible display panel 322, a digitizer 340 disposed under the flexible display panel, support plates 3613 and 3623 disposed under the digitizer and comprising a polymer material, and conductive layers 3611 and 3621 disposed between the digitizer and the support plates and plated on surfaces of the support plates.

According to an embodiment of the disclosure, the support plates 3613 and 3623 may comprise a first support plate 3613 spaced apart from the digitizer and positioned over the first housing, and a second support plate 3623 spaced apart from the digitizer and positioned over the second housing.

According to an embodiment of the disclosure, in a state in which the electronic device is unfolded, the first support plate 3613 and the second support plate 3623 may be arranged side by side with each other with respect to a folding axis FX.

According to an embodiment of the disclosure, the conductive layers 3611 and 3621 may comprise a first conductive layer 3611 spaced apart from the digitizer and positioned on at least one of an upper surface or a lower surface of the first support plate, and a second conductive layer 3621 spaced apart from the digitizer and positioned on at least one of an upper surface or a lower surface of the second support plate.

According to an embodiment of the disclosure, in a state in which the electronic device is unfolded, the first conductive layer 3611 and the second conductive layer 3621 may be arranged side by side with each other with respect to a folding axis FX.

According to an embodiment of the disclosure, the first conductive layer is formed on an upper surface of the first support plate, the thickness of the first conductive layer has 1 [symbol] to 6 [symbol] , the second conductive layer is formed on an upper surface of the second support plate, and the thickness of the second conductive layer may have 1 [symbol] to 6 [symbol] .

According to an embodiment of the disclosure, the first conductive layer is formed on an upper surface and a lower surface of the first support plate, respectively, and the thickness of each of the first conductive layers formed on the upper surface and the lower surface may have 1 [symbol] to 3 [symbol] . The second conductive layer is formed on an upper surface and a lower surface of the second support plate, respectively, and the thickness of each of the second conductive layers formed on the upper surface and the lower surface may have 1 [symbol] to 3 [symbol] .

According to an embodiment of the disclosure, the display device may further comprise a shielding layer 350 disposed under the digitizer and comprising magnetic metal powder (MMP), and a bonding layer 3612 and 3622 disposed between the shielding layer and the conductive layer.

According to an embodiment of the disclosure, the bonding layer 3612 and 3622 may comprise at least one of a pressure sensitive adhesive or a polyethylene terephthalate (PET) layer.

According to an embodiment of the disclosure, the support plates 3613 and 3623 may comprise at least one of carbon fiber reinforced plastics (CFRP) or glass fiber reinforced plastics (GFRP).

According to an embodiment of the disclosure, a density of the support plates 3613 and 3623 may be 1.6 g/cm³ to 2.3 g/cm³.

According to an embodiment of the disclosure, the conductive layers 3611 and 3621 may comprise a copper (Cu) plating layer.

According to an embodiment of the disclosure, the conductive layers 3611 and 3621 may further comprise an Ni/P plating layer plated on one surface of the copper (Cu) plating layer.

According to an embodiment of the disclosure, the display device may further comprise a reinforcement layer 330 disposed between the flexible display panel and the digitizer and supporting the flexible display panel.

According to an embodiment of the disclosure, the reinforcement layer and the support plates 3613 and 3623 of the support layer may be formed of a material of an identical material to each other.

According to an embodiment of the disclosure, the reinforcement layer may comprise a lattice pattern corresponding to a folding area of the display device.

According to an embodiment of the disclosure, a support layer 360 structure formed by a stacked configuration of the support plates 3613 and 3623, the conductive layers 3611 and 3621, and the bonding layers 3612 and 3622 may have a thickness of 106 [symbol] to 112 [symbol] .

According to an embodiment of the disclosure, a support layer 360 structure formed by a stacked configuration of the support plates 3613 and 3623, the conductive layers 3611 and 3621, and the bonding layers 3612 and 3622 may have a weight of 1.3 g to 2.0 g.

A display device 230 according to an embodiment of the disclosure may comprise a flexible display panel 230, a digitizer 340 disposed below the flexible display panel, a shielding layer 350 disposed below the digitizer and comprising magnetic metal powder (MMP), a support plate 3613 and 3623 disposed below the shielding layer and comprising a polymer material, and a conductive layer 3611 and 3621 disposed between the shielding layer and the support plate and plated on a surface of the support plate.

According to an embodiment of the disclosure, the conductive layer may be formed on an upper surface of the support plate, and a thickness of the conductive layer may have 1 [symbol] to 6 [symbol] .

According to an embodiment of the disclosure, the conductive layer may be formed on an upper surface and a lower surface of the support plate, respectively, and a thickness of each of the conductive layers formed on the upper surface and the lower surface may have 1 [symbol] to 3 [symbol] .

According to an embodiment of the disclosure, the support plates 3613 and 3623 may comprise at least one of carbon fiber reinforced plastics (CFRP) or glass fiber reinforced plastics (GFRP).

According to an embodiment of the disclosure, a density of the support plates 3613 and 3623 may be 1.6 g/cm³ to 2.3 g/cm³, and the conductive layers 3611 and 3621 may comprise a copper (Cu) plating layer.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device, cause the electronic device to perform a method of the disclosure.

Any such software may be stored in the form of volatile or non-volatile storage, such as, for example, a storage device like read only memory (ROM), whether erasable or rewritable or not, or in the form of memory, such as, for example, random access memory (RAM), memory chips, device or integrated circuits or on an optically or magnetically readable medium, such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method of any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a first housing;
a second housing; and
a display device disposed on the first housing and the second housing,
wherein the display device comprises:
a flexible display panel,
a digitizer disposed below the flexible display panel,
a support plate disposed below the digitizer and comprising a polymer material, and
a conductive layer disposed between the digitizer and the support plate and plated on a surface of the support plate.

2. The electronic device of claim 1,
wherein the support plate comprises a first support plate spaced apart from the digitizer and positioned above the first housing, and a second support plate spaced apart from the digitizer and positioned above the second housing, and
wherein, in a state in which the electronic device is unfolded, the first support plate and the second support plate are arranged parallel to each other with respect to a folding axis.

3. The electronic device of claim 2,
wherein the conductive layer comprises a first conductive layer spaced apart from the digitizer and positioned on at least one of an upper surface or a lower surface of the first support plate, and a second conductive layer spaced apart from the digitizer and positioned on at least one of an upper surface or a lower surface of the second support plate, and
wherein, in a state in which the electronic device is unfolded, the first conductive layer and the second conductive layer are arranged parallel to each other with respect to the folding axis.

4. The electronic device of claim 3,
wherein the first conductive layer is formed on an upper surface of the first support plate, and the first conductive layer has a thickness of 1 [symbol] to 6 [symbol] , and
wherein the second conductive layer is formed on an upper surface of the second support plate, and the second conductive layer has a thickness of 1 [symbol] to 6 [symbol] .

5. The electronic device of claim 3,
wherein the first conductive layer is formed on an upper surface and a lower surface of the first support plate, respectively, and each of the first conductive layers formed on the upper surface and the lower surface has a thickness of 1 [symbol] to 3 [symbol] , and
wherein the second conductive layer is formed on an upper surface and a lower surface of the second support plate, respectively, and each of the second conductive layers formed on the upper surface and the lower surface has a thickness of 1 [symbol] to 3 [symbol] .

6. The electronic device of claim 1, wherein the display device further comprises:
a shielding layer disposed below the digitizer and comprising magnetic metal powder (MMP); and
a bonding layer disposed between the shielding layer and the conductive layer.

7. The electronic device of claim 6, wherein the bonding layer comprises at least one of a pressure sensitive adhesive or a polyethylene terephthalate (PET) layer.

8. The electronic device of claim 1, wherein the support plate comprises at least one of carbon fiber reinforced plastics (CFRP) or glass fiber reinforced plastics (GFRP).

9. The electronic device of claim 1, wherein a density of the support plate is 1.6 g/cm³ to 2.3 g/cm³.

10. The electronic device of claim 1, wherein the conductive layer comprises a copper (Cu) plating layer.

11. The electronic device of claim 10, wherein the conductive layer further comprises a Ni/P plating layer plated on one surface of the copper (Cu) plating layer.

12. The electronic device of claim 1,
wherein the display device further comprises a reinforcement layer disposed between the flexible display panel and the digitizer and supporting the flexible display panel, and
wherein the reinforcement layer and the support plate are formed of the same material.

13. The electronic device of claim 12, wherein the reinforcement layer comprises a lattice pattern corresponding to a folding area of the display device.

14. The electronic device of claim 6, wherein a support layer structure formed by a stacked configuration of the support plate, the conductive layer, and the bonding layer has a thickness of 106 [symbol] to 112 [symbol] .

15. The electronic device of claim 6, wherein a support layer structure formed by a stacked configuration of the support plate, the conductive layer, and the bonding layer has a weight of 1.3 g to 2.0 g.

16. A display device comprising:
a flexible display panel;
a digitizer disposed below the flexible display panel;
a shielding layer disposed below the digitizer and including a magnetic metal powder (MMP);
a support plate disposed below the shielding layer and including a polymer material; and
a conductive layer disposed between the shielding layer and the support plate and plated on a surface of the support plate.

17. The display device of claim 16, wherein the conductive layer is formed on an upper surface of the support plate, and a thickness of the conductive layer is 1 [symbol] to 6 [symbol] .

18. The display device of claim 16, wherein the conductive layer is formed on an upper surface and a lower surface of the support plate, respectively, and a thickness of each of the conductive layers formed on the upper surface and the lower surface is 1 [symbol] to 3 [symbol] .

19. The display device of claim 16, wherein the support plate comprises at least one of carbon fiber reinforced plastics (CFRP) or glass fiber reinforced plastics (GFRP).

20. The display device of claim 16, wherein a density of the support plate is 1.6 g/cm³ to 2.3 g/cm³, and the conductive layer comprises a copper (Cu) plating layer.
